(19) United States
(12) Patent Application Publication
(10) Pub. No.: US 2024/0292661 A1
(43) Pub. Date: Aug. 29, 2024

(54) DISPLAY DEVICE

(71) Applicant: Samsung Display Co., Ltd., Yongin-si (KR)

(72) Inventors: JIHYE LEE, Yongin-si (KR); JINSEON KWAK, Yongin-si (KR); YONGHEE LEE, Yongin-si (KR)

(21) Appl. No.: 18/583,514

(22) Filed: Feb. 21, 2024

(30) Foreign Application Priority Data
Feb. 24, 2023 (KR) 10-2023-0025120

(51) Int. Cl. H10K 59/121; H10K 59/131

(52) U.S. Cl. CPC H10K 59/1213; H10K 59/131

(57) ABSTRACT

A display device includes: a substrate including: a first well area; and a second well area spaced from the first well area, the second well area having a voltage different from a voltage of the first well area; a first pixel circuit including: a first transistor located on the first well area; and a second transistor located on the second well area; and a second pixel circuit including: a third transistor located on the first well area; and a fourth transistor located on the second well area.

### CROSS-REFERENCE TO RELATED APPLICATION

The present application claims priority to and the benefit of Korean Patent Application No. 10-2023-0025120, filed on Feb. 24, 2023, in the Korean Intellectual Property Office (KIPO), the entire content of which is incorporated by reference herein.

### BACKGROUND

### 1. Field

Aspects of embodiments of the present disclosure relate to a display device.

### 2. Description of Related Art

A display device is a device that displays an image for providing visual information to a user. From among various kinds of display devices, an organic light emitting diode display has recently attracted attention.

A head mounted display (“HMD”) may be used for virtual reality (“VR”) or augmented reality (“AR”). A micro display may be applied to various products, such as the head mounted display. An organic light emitting diode on silicon (“OLEDoS”) display may be used as the micro display.

The above information disclosed in this Background section is for enhancement of understanding of the background of the present disclosure, and therefore, it may contain information that does not constitute prior art.

### SUMMARY

In an organic light emitting diode on silicon display, an anode electrode, an organic light emitting layer, and a cathode electrode may be formed on a semiconductor substrate. The semiconductor substrate may include a CMOS circuit for controlling each pixel. The CMOS circuit may be formed on a well.

One or more embodiments of the present disclosure are directed to a display device having improved display quality.

A display device according to one or more embodiments of the present disclosure includes: a substrate including a first well area, and a second well area spaced apart from the first well area; a first pixel circuit including a first transistor disposed on the first well area, and a second transistor disposed on the second well area; and a second pixel circuit including a third transistor disposed on the first well area, and a fourth transistor disposed on the second well area.

In an embodiment, the second well area may have a voltage different from a voltage of the first well area.

In an embodiment, the voltage of the first well area may be higher than the voltage of the second well area.

In an embodiment, the first well area may have a rectangular shape, and the second well area may include: a first portion extending in a first direction and spaced apart from the first well area in a second direction crossing the first direction; a second portion extending in the second direction and spaced apart from the first well area in the first direction, and a third portion in contact with the first portion and the second portion.

In an embodiment, each of the first transistor and the third transistor may be a driving transistor.

In an embodiment, the display device may further include a third pixel circuit including a fifth transistor disposed on the first well area, and a sixth transistor disposed on the second well area.

In an embodiment, the fifth transistor may be a driving transistor.

In an embodiment, the substrate may further include a third well area having a mirror image of the first well area with respect to a first direction, and a fourth well area having a mirror image of the second well area with respect to the first direction.

In an embodiment, the third well area may have a voltage substantially equal to the voltage of the first well area.

In an embodiment, the fourth well area may have a voltage substantially equal to the voltage of the second well area.

In an embodiment, the display device may further include: a fourth pixel circuit including a seventh transistor disposed on the third well area, and an eighth transistor disposed on the fourth well area; a fifth pixel circuit including a ninth transistor disposed on the third well area, and a tenth transistor disposed on the fourth well area; and a sixth pixel circuit including an eleventh transistor disposed on the third well area, and a twelfth transistor disposed on the fourth well area.

In an embodiment, each of the seventh transistor, the ninth transistor, and the eleventh transistor may be a driving transistor.

In an embodiment, the substrate may further include a fifth well area having a mirror image of the first well area with respect to a second direction crossing the first direction, and a sixth well area having a mirror image of the second well area with respect to the second direction.

In an embodiment, the fifth well area may have a voltage substantially equal to the voltage of the first well area.

In an embodiment, the sixth well area may have a voltage substantially equal to the voltage of the second well area.

In an embodiment, the display device may further include: a seventh pixel circuit including a thirteenth transistor disposed on the fifth well area, and a fourteenth transistor disposed on the sixth well area; an eighth pixel circuit including a fifteenth transistor disposed on the fifth well area, and a sixteenth transistor disposed on the sixth well area; and a ninth pixel circuit including a seventeenth transistor disposed on the fifth well area, and an eighteenth transistor disposed on the sixth well area.

In an embodiment, each of the thirteenth transistor, the fifteenth transistor, and the seventeenth transistor may be a driving transistor.

In an embodiment, the substrate may further include a seventh well area having a mirror image of the fifth well area with respect to the first direction, and an eighth well area having a mirror image of the sixth well area with respect to the first direction.

In an embodiment, the seventh well area may have a voltage substantially equal to the voltage of the fifth well area.

In an embodiment, the eighth well area may have a voltage substantially equal to the voltage of the sixth well area.

In an embodiment, the display device may further include: a tenth pixel circuit including a nineteenth transistor disposed on the seventh well area, and a twentieth transistor disposed on the eighth well area; an eleventh pixel circuit including a twenty-first transistor disposed on the seventh well area, and a twenty-second transistor disposed on the eighth well area; and a twelfth pixel circuit including a twenty-third transistor disposed on the seventh well area, and a twenty-fourth transistor disposed on the eighth well area.

In an embodiment, each of the nineteenth transistor, the twenty-first transistor, and the twenty-third transistor may be a driving transistor.

A display device according to one or more embodiments of the present disclosure includes: a substrate including: a first well area having a rectangular shape; a second well area including a first portion extending in a first direction and spaced apart from the first well area in a second direction crossing the first direction, and a second portion extending in the second direction and spaced apart from the first well area in the first well area; and a third well area having a voltage lower than a voltage of the first well area and different from a voltage of the second well area; a first pixel circuit including a first transistor disposed on the first well area, and a second transistor disposed on the second well area or the third well area; a second pixel circuit including a third transistor disposed on the first well area, and a fourth transistor disposed on the second well area or the third well area; and a third pixel circuit including a fifth transistor disposed on the first well area, and a sixth transistor disposed on the second well area or the third well area.

In an embodiment, the second well area may have the voltage lower than the voltage of the first well area, and the third well area may be in contact with the first portion and the second portion.

In an embodiment, the substrate may further include a fourth well area having a mirror image of the first well area with respect to the first direction, a fifth well area having a mirror image of the second well area with respect to the first direction, and a sixth well area having a mirror image of the third well area with respect to the first direction.

In an embodiment, the fourth well area may have a voltage substantially equal to the voltage of the first well area.

In an embodiment, the fifth well area may have a voltage substantially equal to the voltage of the second well area.

In an embodiment, the sixth well area may have a voltage substantially equal to the voltage of the third well area.

In an embodiment, the display device may further include: a fourth pixel circuit including a seventh transistor disposed on the fourth well area, and an eighth transistor disposed on the fifth well area or the sixth well area; a fifth pixel circuit including a ninth transistor disposed on the fourth well area, and a tenth transistor disposed on the fifth well area or the sixth well area; and a sixth pixel circuit including an eleventh transistor disposed on the fourth well area, and a twelfth transistor disposed on the fifth well area or the sixth well area.

In an embodiment, each of the seventh transistor, the ninth transistor, and the eleventh transistor may be a driving transistor.

In an embodiment, the substrate may further include a seventh well area having a mirror image of the first well area with respect to the second direction, an eighth well area having a mirror image of the second well area with respect to the second direction, and a ninth well area having a mirror image of the third well area with respect to the second direction.

In an embodiment, the seventh well area may have a voltage substantially equal to the voltage of the first well area.

In an embodiment, the eighth well area may have a voltage substantially equal to the voltage of the second well area.

In an embodiment, the ninth well area may have a voltage substantially equal to the voltage of the third well area.

In an embodiment, the display device may further include: a seventh pixel circuit including a thirteenth transistor disposed on the seventh well area, and a fourteenth transistor disposed on the eighth well area or the ninth well area; an eighth pixel circuit including a fifteenth transistor disposed on the seventh well area, and a sixteenth transistor disposed on the eighth well area or the ninth well area; and a ninth pixel circuit including a seventeenth transistor disposed on the seventh well area, and an eighteenth transistor disposed on the eighth well area or the ninth well area.

In an embodiment, each of the thirteenth transistor, the fifteenth transistor, and the seventeenth transistor may be a driving transistor.

In an embodiment, the substrate may further include a tenth well area having a mirror image of the seventh well area with respect to the first direction, an eleventh well area having a mirror image of the eighth well area with respect to the first direction, and a twelfth well area having a mirror image of the ninth well area with respect to the first direction.

In an embodiment, the tenth well area may have a voltage substantially equal to the voltage of the seventh well area.

In an embodiment, the eleventh well area may have a voltage substantially equal to the voltage of the eighth well area.

In an embodiment, the twelfth well area may have a voltage substantially equal to the voltage of the ninth well area.

In an embodiment, the display device may further include: a tenth pixel circuit including a nineteenth transistor disposed on the tenth well area, and a twentieth transistor disposed on the eleventh well area or the twelfth well area; an eleventh pixel circuit including a twenty-first transistor disposed on the tenth well area, and a twenty-second transistor disposed on the eleventh well area or the twelfth well area; and a twelfth pixel circuit including a twenty-third transistor disposed on the tenth well area, and a twenty-fourth transistor disposed on the eleventh well area or the twelfth well area.

In an embodiment, each of the nineteenth transistor, the twenty-first transistor, and the twenty-third transistor may be a driving transistor.

A display device according to one or more embodiments of the present disclosure includes: a substrate including: a first well area having a rectangular shape; a second well area having a voltage lower than a voltage of the first well area, extending in a first direction, and spaced apart from the first well area in a second direction crossing the first direction; a third well area having a voltage lower than the voltage of the first well area and different from the voltage of the second well area, extending in the second direction, and spaced apart from the first well area in the first direction; and a fourth well area having a voltage lower than the voltage of the first well area and different from each of the voltage of the second well area and the voltage of the third well area, and in contact with the second well area and the third well area; a first pixel circuit including a first transistor disposed on the first well area, and a second transistor disposed on the second well area, the third well area, or the fourth well area; a second pixel circuit including a third transistor disposed on the first well area, and a fourth transistor disposed on the second well area, the third well area, or the fourth well area; and a third pixel circuit including a fifth transistor disposed on the first well area, and a sixth transistor disposed on the second well area, the third well area, or the fourth well area.

In an embodiment, the substrate may further include a fifth well area having a mirror image of the first well area with respect to the first direction, a sixth well area having a mirror image of the second well area with respect to the first direction, a seventh well area having a mirror image of the third well area with respect to the first direction, and an eighth well area having a mirror image of the fourth well area with respect to the first direction.

In an embodiment, the fifth well area may have a voltage substantially equal to the voltage of the first well area.

In an embodiment, the sixth well area may have a voltage substantially equal to the voltage of the second well area.

In an embodiment, the seventh well area may have a voltage substantially equal to the voltage of the third well area.

In an embodiment, the eighth well area may have a voltage substantially equal to the voltage of the fourth well area.

In an embodiment, the display device may further include: a fourth pixel circuit including a seventh transistor disposed on the fifth well area, and an eighth transistor disposed on the sixth well area, the seventh well area, or the eighth well area; a fifth pixel circuit including a ninth transistor disposed on the fifth well area, and a tenth transistor disposed on the sixth well area, the seventh well area, or the eighth well area; and a sixth pixel circuit including a eleventh transistor disposed on the fifth well area, and a twelfth transistor disposed on the sixth well area, the seventh well area, or the eighth well area.

In an embodiment, each of the seventh transistor, the ninth transistor, and the eleventh transistor may be a driving transistor.

In an embodiment, the substrate may further include a ninth well area having a mirror image of the first well area with respect to the second direction, a tenth well area having a mirror image of the second well area with respect to the second direction, an eleventh well area having a mirror image of the third well area with respect to the second direction, and a twelfth well area having a mirror image of the fourth well area with respect to the second direction. The twelfth well area may have a voltage substantially equal to the voltage of the fourth well area.

In an embodiment, the ninth well area may have a voltage substantially equal to the voltage of the first well area.

In an embodiment, the tenth well area may have a voltage substantially equal to the voltage of the second well area.

In an embodiment, the eleventh well area may have a voltage substantially equal to the voltage of the third well area.

In an embodiment, the twelfth well area may have a voltage substantially equal to the voltage of the fourth well area.

In an embodiment, the display device may further include: a seventh pixel circuit including a thirteenth transistor disposed on the ninth well area, and a fourteenth transistor disposed on the tenth well area, the eleventh well area, or the twelfth well area; an eighth pixel circuit including a fifteenth transistor disposed on the ninth well area, and a sixteenth transistor disposed on the tenth well area, the eleventh well area, or the twelfth well area; and a ninth pixel circuit including a seventeenth transistor disposed on the ninth well area, and an eighteenth transistor disposed on the tenth well area, the eleventh well area, or the twelfth well area.

In an embodiment, each of the thirteenth transistor, the fifteenth transistor, and the seventeenth transistor may be a driving transistor.

In an embodiment, the substrate may further include a thirteenth well area having a mirror image of the ninth well area with respect to the first direction, a fourteenth well area having a mirror image of the tenth well area with respect to the first direction, a fifteenth well area having a mirror image of the eleventh well area with respect to the first direction, and a sixteenth well area having a mirror image of the twelfth well area with respect to the first direction.

In an embodiment, the thirteenth well area may have a voltage substantially equal to the voltage of the ninth well area.

In an embodiment, the fourteenth well area may have a voltage substantially equal to the voltage of the tenth well area.

In an embodiment, the fifteenth well area may have a voltage substantially equal to the voltage of the eleventh well area.

In an embodiment, the sixteenth well area may have a voltage substantially equal to the voltage of the twelfth well area.

In an embodiment, the display device may further include: a tenth pixel circuit including a nineteenth transistor disposed on the thirteenth well area, and a twentieth transistor disposed on the fourteenth well area, the fifteenth well area, or the sixteenth well area; an eleventh pixel circuit including a twenty-first transistor disposed on the thirteenth well area, and a twenty-second transistor disposed on the fourteenth well area, the fifteenth well area, or the sixteenth well area; and a twelfth pixel circuit including a twenty-third transistor disposed on the thirteenth well area, and a twenty-fourth transistor disposed on the fourteenth well area, the fifteenth well area, or the sixteenth well area.

In an embodiment, each of the nineteenth transistor, the twenty-first transistor, and the twenty-third transistor may be a driving transistor.

A display device according to one or more embodiments of the present disclosure includes: a substrate including a first well area, and a second well area spaced apart from the first well area; a first pixel circuit including a first transistor disposed on the first well area, and a second transistor disposed on the second well area; and a second pixel circuit including a third transistor disposed on the first well area, and a fourth transistor disposed on the second well area. In addition, the second well area may have a voltage different from a voltage of the first well area.

In other words, a plurality of transistors may be formed on one well. In this case, high voltage transistors, such as driving transistors, may be formed on a high voltage well. In addition, low voltage transistors, such as switching transistors, may be formed on a low voltage well.

According to one or more embodiments of the present disclosure, because both the high voltage well and the low voltage well may be disposed, the high voltage transistor and the low voltage transistor may be positioned separately from each other. In addition, transistors may be disposed adjacent to each other on a designated well. As such, intervals between pixels may be reduced (e.g., may be narrowed). Accordingly, a resolution of the display device may be improved.

### BRIEF DESCRIPTION OF THE DRAWINGS

The above and other aspects and features of the present disclosure will be more clearly understood from the following detailed description of the illustrative, non-limiting embodiments with reference to the accompanying drawings.

FIG. 1 is a schematic plan view illustrating a display device according to an embodiment.

FIG. 2 is a circuit diagram illustrating a first sub-pixel included in the display device of FIG. 1.

FIGS. 3 through 5 are enlarged plan views illustrating the portion P of FIG. 1.

FIG. 6 is a schematic cross-sectional view of the display device taken along the X-Y line of FIG. 4.

FIG. 7 is a schematic cross-sectional view of the display device taken along the A-B line of FIG. 5.

FIG. 8 is a schematic plan view illustrating a plurality of wells included in a display device according to an embodiment.

FIG. 9 is a schematic plan view illustrating a plurality of wells included in a display device according to an embodiment.

FIG. 10 is a schematic plan view illustrating a plurality of wells and transistors included in the display device of FIG. 8.

FIG. 11 is a schematic plan view illustrating a plurality of wells included in a display device according to an embodiment.

FIG. 12 is a schematic plan view illustrating a plurality of wells included in a display device according to an embodiment.

FIG. 13 is a schematic plan view illustrating a plurality of wells and transistors included in the display device of FIG. 12.

### DETAILED DESCRIPTION

Hereinafter, display devices in accordance with embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

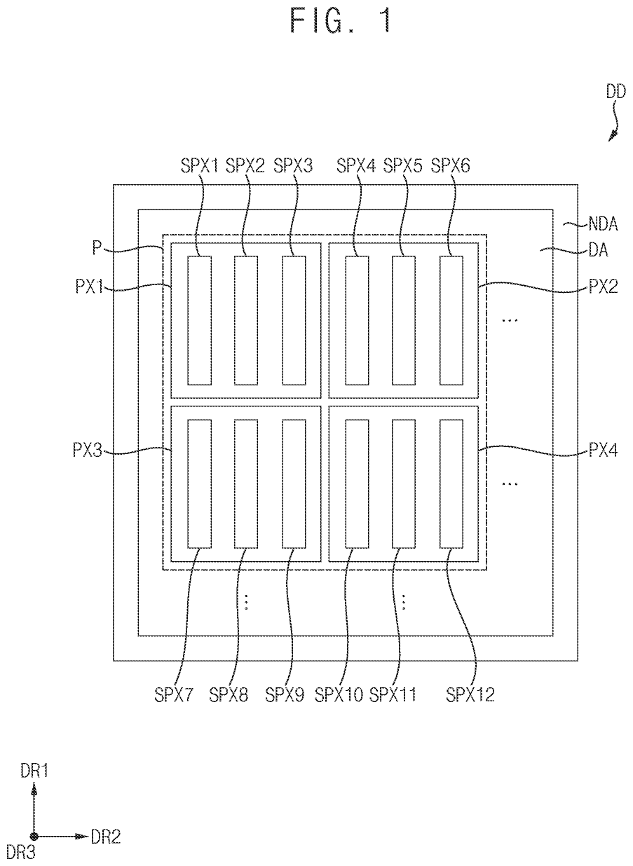

FIG. 1 is a schematic plan view illustrating a display device according to an embodiment.

Referring to FIG. 1, a display device DD according to an embodiment may include a display area DA and a non-display area NDA. The display area DA may be defined as an area capable of generating light, or displaying an image by adjusting a transmittance of light provided from an external light source.

The non-display area NDA may be defined as an area that does not display an image. In addition, the non-display area NDA may surround (e.g., around a periphery of) at least a portion of the display area DA. For example, the non-display area NDA may entirely surround (e.g., around the periphery of) the display area DA.

In an embodiment, the display device DD may have a rectangular shape in a plan view. However, the present disclosure is not limited thereto, and in another embodiment, the display device DD may have a different shape in a plane (e.g., in a plan view).

A plurality of pixels may be disposed in the display area DA. For example, a first pixel PX1, a second pixel PX2, a third pixel PX3, and a fourth pixel PX4 may be disposed in the display area DA. Each of the plurality of pixels may emit light. Accordingly, the display area DA of the display device DD may display an image.

The plurality of pixels may be repeatedly arranged along a first direction DR1, and a second direction DR2 crossing the first direction DR1. For example, the second pixel PX2 may be spaced apart from the first pixel PX1 in the second direction DR2. In addition, the third pixel PX3 may be spaced apart from the first pixel PX1 in a direction opposite to the first direction DR1.

Each of the plurality of pixels may include a plurality of sub-pixels. For example, the first pixel PX1 may include a first sub-pixel SPX1, a second sub-pixel SPX2, and a third sub-pixel SPX3. In addition, the second pixel PX2 may include a fourth sub-pixel SPX4, a fifth sub-pixel SPX5, and a sixth sub-pixel SPX6. The third pixel PX3 may include a seventh sub-pixel SPX7, an eighth sub-pixel SPX8, and a ninth sub-pixel SPX9. The fourth pixel PX4 may include a tenth sub-pixel SPX10, an eleventh sub-pixel SPX11, and a twelfth sub-pixel SPX12.

The first sub-pixel SPX1 may emit a first light, the second sub-pixel SPX2 may emit a second light, and the third sub-pixel SPX3 may emit a third light. In an embodiment, the first light may be red light, the second light may be green light, and the third light may be blue light. However, the present disclosure is not limited thereto, and in another embodiment, the first light may be green light, the second light may be blue light, and the third light may be red light. In another embodiment, the first sub-pixel SPX1, the second sub-pixel SPX2, and the third sub-pixel SPX3 may be combined with each other to emit yellow light, cyan light, magenta light, or the like.

Because each of the first sub-pixel SPX1, the second sub-pixel SPX2, and the third sub-pixel SPX3 emits light, the first pixel PX1 may emit light of a desired wavelength (e.g., a specific or predetermined wavelength). This may be applied in the same or substantially the same way for the second pixel PX2, the third pixel PX3, and the fourth pixel PX4.

The non-display area NDA may be disposed around (e.g., adjacent to) the display area DA. A driving unit (e.g., a driver or a driving circuit) may be disposed in the non-display area NDA. The driving unit may provide a signal or a voltage to the plurality of pixels. For example, the driving unit may include a data driving unit (e.g., a data driver), a gate driving unit (e.g., a gate driver), and/or the like.

The first direction DR1 and the second direction DR2 may be perpendicular or substantially perpendicular to each other. In addition, a third direction DR3 (e.g., a thickness direction) may be perpendicular or substantially perpendicular to a plane formed by the first direction DR1 and the second direction DR2.

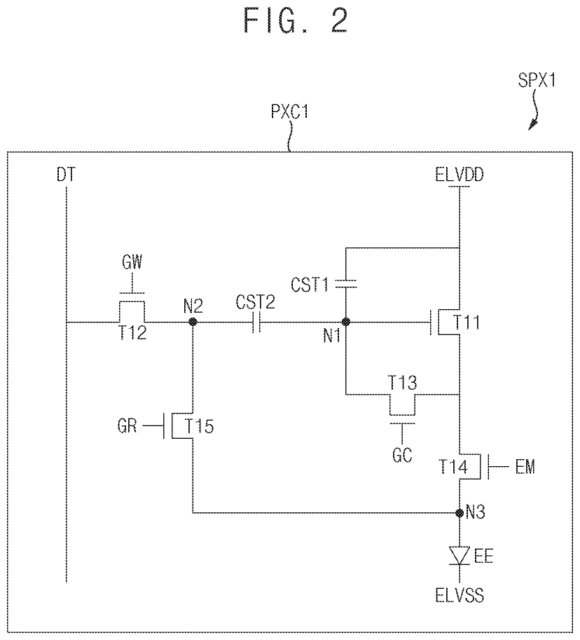

FIG. 2 is a circuit diagram illustrating the first sub-pixel included in the display device of FIG. 1.

Referring to FIG. 2, the first sub-pixel SPX1 may include a first pixel circuit PXC1. The first pixel circuit PXC1 may include a first transistor T11, a second transistor T12, a third transistor T13, a fourth transistor T14, a fifth transistor T15, a first capacitor CST1, a second capacitor CST2, and a light emitting element EE.

The first transistor T11 may include a first electrode to which a first power voltage ELVDD is applied, a gate electrode connected to a first node N1, and a second electrode connected to a first electrode of the fourth transistor T14. The first transistor T11 may apply a driving current to the light emitting element EE. In other words, the first transistor T11 may be a driving transistor.

The second transistor T12 may include a first electrode to which a data voltage DT is applied, a gate electrode to which a first write gate signal GW is applied, and a second electrode connected to a second node N2.

The third transistor T13 may include a first electrode connected to the first node N1, a gate electrode to which a compensation gate signal GC is applied, and a second electrode connected to the first electrode of the fourth transistor T14.

The fourth transistor T14 may include a first electrode connected to the second electrode of the first transistor T11, a gate electrode to which an emission signal EM is applied, and a second electrode connected to a third node N3.

The fifth transistor T15 may include a first electrode connected to the second node N2, a gate electrode to which a second write gate signal GR is applied, and a second electrode connected to the third node N3.

The first capacitor CST1 may include a first electrode connected to the first power voltage ELVDD, and a second electrode connected to the first node N1.

The second capacitor CST2 may include a first electrode connected to the second node N2, and a second electrode connected to the first node N1.

The light emitting element EE may include a first electrode connected to the third node N3, and a second electrode connected to a second power voltage ELVSS.

FIG. 2 illustrates an example in which the first pixel circuit PXC1 includes the first transistor T11, the second transistor T12, the third transistor T13, the fourth transistor T14, the fifth transistor T15, the first capacitor CST1, and the second capacitor CST2. In other words, FIG. 2 may illustrate an example in which the first pixel circuit PXC1 includes a 5T2C (5 Transistor-2 Capacitor) structure. However, the present disclosure is not limited to it, and the first pixel circuit PXC1 may include other suitable structures, such as a 2T1C structure, a 7T1C structure, a 6T1C structure, or the like, as would be understood by those having ordinary skill in the art.

In addition, FIG. 2 illustrates a circuit structure of the first pixel circuit PXC1. However, each of a second pixel circuit PXC2, a third pixel circuit PXC3, a fourth pixel circuit PXC4, a fifth pixel circuit PXC5, a sixth pixel circuit PXC6, a seventh pixel circuit PXC7, an eighth pixel circuit PXC8, a ninth pixel circuit PXC9, a tenth pixel circuit PXC10, an eleventh pixel circuit PXC11, and a twelfth pixel circuit PXC12 described in more detail below may also have the same or substantially the same circuit structure as that illustrated in FIG. 2, and thus, redundant description thereof may not be repeated.

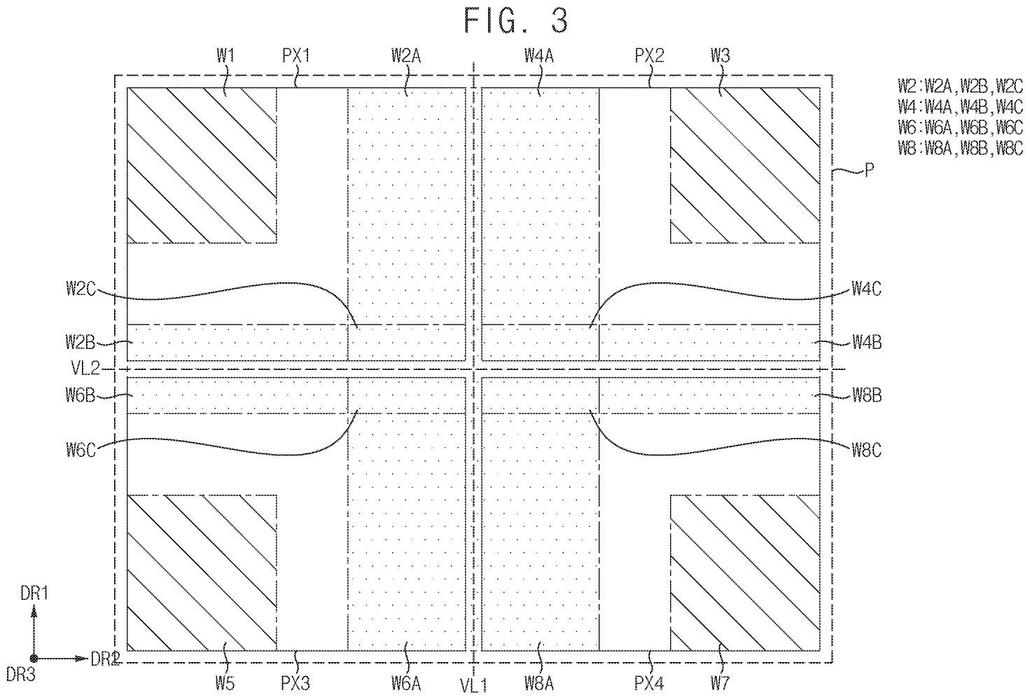

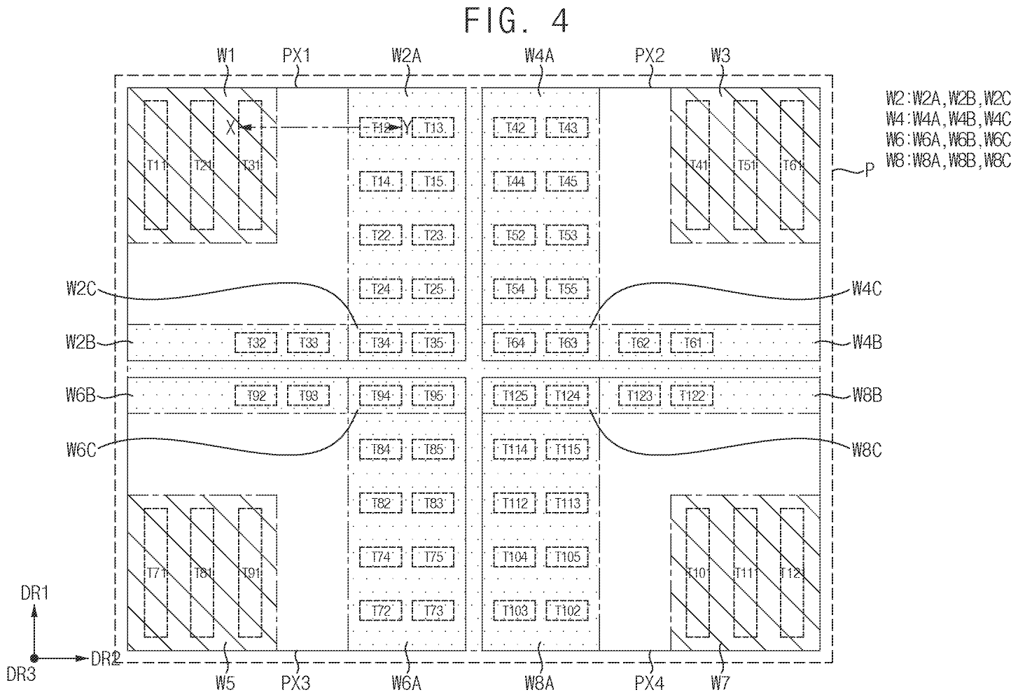

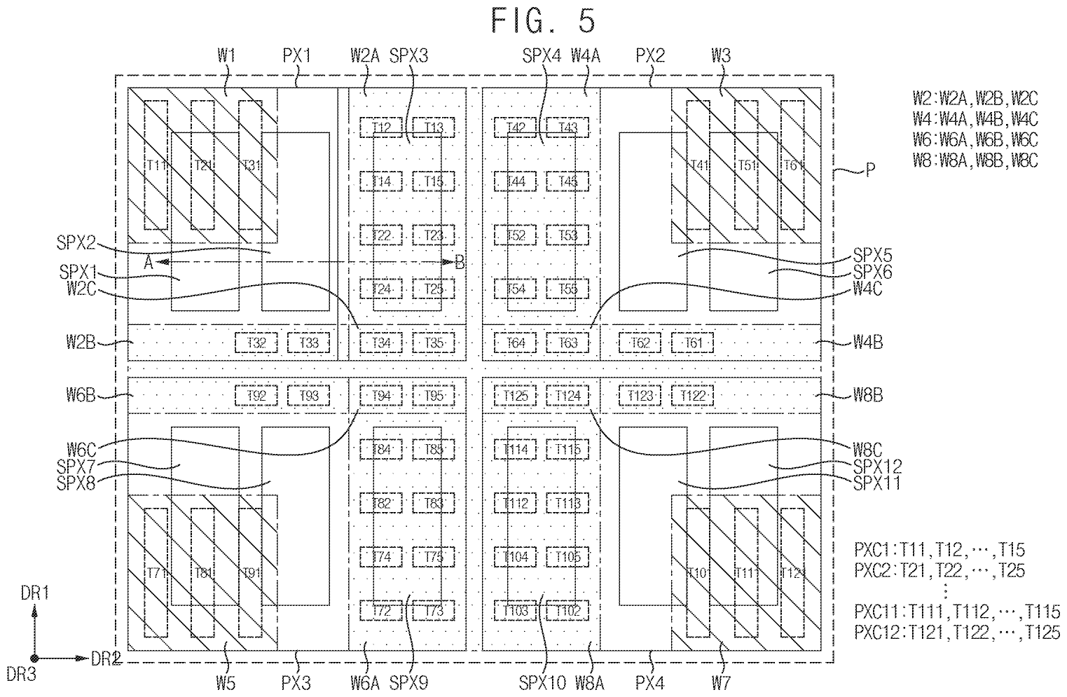

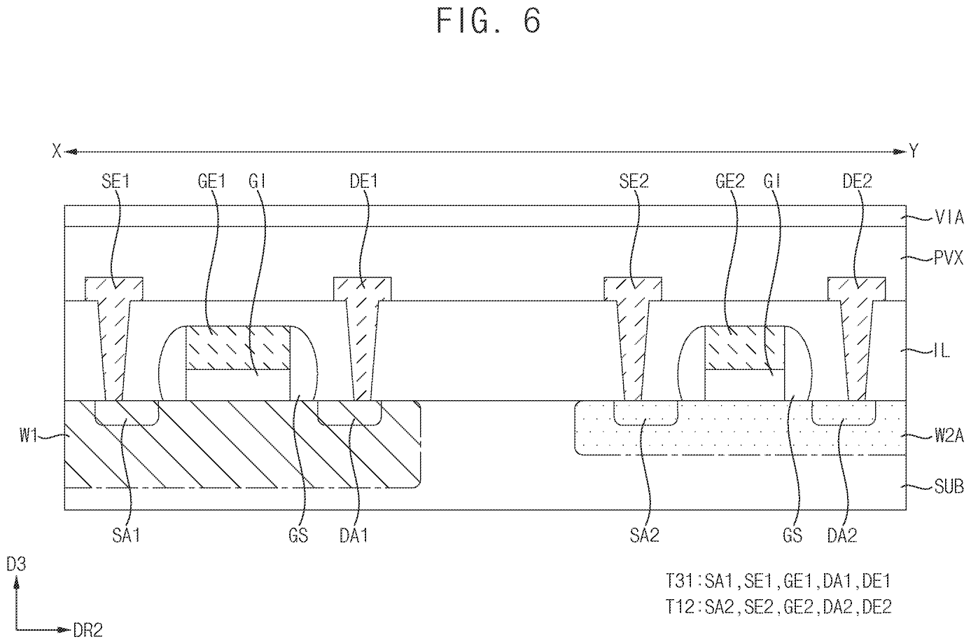

FIGS. 3, 4, and 5 are enlarged plan views illustrating the portion P of FIG. 1. FIG. 6 is a schematic cross-sectional view of the display device taken along the X-Y line of FIG. 4. For example, FIG. 3 is a plan view illustrating a plurality of well areas. FIG. 4 is a plan view illustrating a plurality of transistors that are disposed on the plurality of well areas. FIG. 5 is a plan view illustrating the plurality of well areas, the plurality of transistors, and a plurality of sub-pixels.

Referring to FIGS. 2, 3, 4, and 5, the first pixel PX1 may include the first sub-pixel SPX1, the second sub-pixel SPX2, and the third sub-pixel SPX3.

The first sub-pixel SPX1 may include the first pixel circuit PXC1. The first pixel circuit PXC1 may include the first transistor T11, the second transistor T12, the third transistor T13, the fourth transistor T14, and the fifth transistor T15.

The second sub-pixel SPX2 may include the second pixel circuit PXC2. The second pixel circuit PXC2 may include a first transistor T21, a second transistor T22, a third transistor T23, a fourth transistor T24, and a fifth transistor T25.

The third sub-pixel SPX3 may include the third pixel circuit PXC3. The third pixel circuit PXC3 may include a first transistor T31, a second transistor T32, a third transistor T33, a fourth transistor T34, and a fifth transistor T35.

The second pixel PX2 may include the fourth sub-pixel SPX4, the fifth sub-pixel SPX5, and the sixth sub-pixel SPX6.

The fourth sub-pixel SPX4 may include the fourth pixel circuit PXC4. The fourth pixel circuit PXC4 may include a first transistor T41, a second transistor T42, a third transistor T43, a fourth transistor T44, and a fifth transistor T45.

The fifth sub-pixel SPX5 may include the fifth pixel circuit PXC5. The fifth pixel circuit PXC5 may include a first transistor T51, a second transistor T52, a third transistor T53, a fourth transistor T54, and a fifth transistor T55.

The sixth sub-pixel SPX6 may include the sixth pixel circuit PXC6. The sixth pixel circuit PXC6 may include a first transistor T61, a second transistor T62, a third transistor T63, a fourth transistor T64, and a fifth transistor T65.

The third pixel PX3 may include the seventh sub-pixel SPX7, the eighth sub-pixel SPX8, and the ninth sub-pixel SPX9.

The seventh sub-pixel SPX7 may include the seventh pixel circuit PXC7. The seventh pixel circuit PXC7 may include a first transistor T71, a second transistor T72, a third transistor T73, a fourth transistor T74, and a fifth transistor T75.

The eighth sub-pixel SPX8 may include the eighth pixel circuit PXC8. The eighth pixel circuit PXC8 may include a first transistor T81, a second transistor T82, a third transistor T83, a fourth transistor T84, and a fifth transistor T85.

The ninth sub-pixel SPX9 may include the ninth pixel circuit PXC9. The ninth pixel circuit PXC9 may include a first transistor T91, a second transistor T92, a third transistor T93, a fourth transistor T94, and a fifth transistor T95.

The fourth pixel PX4 may include the tenth sub-pixel SPX10, the eleventh sub-pixel SPX11, and the twelfth sub-pixel SPX12.

The tenth sub-pixel SPX10 may include the tenth pixel circuit PXC10. The tenth pixel circuit PXC10 may include a first transistor T101, a second transistor T102, a third transistor T103, a fourth transistor T104, and a fifth transistor T105.

The eleventh sub-pixel SPX11 may include the eleventh pixel circuit PXC11. The eleventh pixel circuit PX11 may include a first transistor T111, a second transistor T112, a third transistor T113, a fourth transistor T114, and a fifth transistor T115.

The twelfth sub-pixel SPX12 may include the twelfth pixel circuit PXC12. The twelfth pixel circuit PXC12 may include a first transistor T121, a second transistor T122, a third transistor T123, a fourth transistor T124, and a fifth transistor T125.

In an embodiment, each of the first transistor T11 included in the first pixel circuit PXC1, the first transistor T21 included in the second pixel circuit PXC2, the first transistor T31 included in the third pixel circuit PXC3, the first transistor T41 included in the fourth pixel circuit PXC4, the first transistor T51 included in the fifth pixel circuit PXC5, the first transistor T61 included in the sixth pixel circuit PXC6, the first transistor T71 included in the seventh pixel circuit PXC7, the first transistor T81 included in the eighth pixel circuit PXC8, the first transistor T91 included in the ninth pixel circuit PXC9, the first transistor T101 included in the tenth pixel circuit PXC10, the first transistor T111 included in the eleventh pixel circuit PXC11, and the first transistor T121 included in the twelfth pixel circuit PXC12 may be a driving transistor.

In an embodiment, the second transistor T22, the third transistor T23, the fourth transistor T24, and the fifth transistor T25 included in the second pixel circuit PXC2 may correspond to (e.g., may be the same or substantially the same as) the second transistor T12, the third transistor T13, the fourth transistor T14, and the fifth transistor T15 included in the first pixel circuit PXC1, respectively. In addition, the second transistor T32, the third transistor T33, the fourth transistor T34, and the fifth transistor T35 included in the third pixel circuit PXC3 may correspond to (e.g., may be the same or substantially the same as) the second transistor T12, the third transistor T13, the fourth transistor T14, and the fifth transistor T15 included in the first pixel circuit PXC1, respectively.

In addition, the second transistor T42, the third transistor T43, the fourth transistor T44, and the fifth transistor T45 included in the fourth pixel circuit PXC4 may correspond to (e.g., may be the same or substantially the same as) the second transistor T12, the third transistor T13, the fourth transistor T14, and the fifth transistor T15 included in the first pixel circuit PXC1, respectively. In addition, the second transistor T52, the third transistor T53, the fourth transistor T54, and the fifth transistor T55 included in the fifth pixel circuit PXC5 may correspond to (e.g., may be the same or substantially the same as) the second transistor T12, the third transistor T13, the fourth transistor T14, and the fifth transistor T15 included in the first pixel circuit PXC1, respectively.

In addition, the second transistor T62, the third transistor T63, the fourth transistor T64, and the fifth transistor T65 included in the sixth pixel circuit PXC6 may correspond to (e.g., may be the same or substantially the same as) the second transistor T12, the third transistor T13, the fourth transistor T14, and the fifth transistor T15 included in the first pixel circuit PXC1, respectively. In addition, the second transistor T72, the third transistor T73, the fourth transistor T74, and the fifth transistor T75 included in the seventh pixel circuit PXC7 may correspond to (e.g., may be the same or substantially the same as) the second transistor T12, the third transistor T13, the fourth transistor T14, and the fifth transistor T15 included in the first pixel circuit PXC1, respectively.

In addition, the second transistor T82, the third transistor T83, the fourth transistor T84, and the fifth transistor T85 included in the eighth pixel circuit PXC8 may correspond to (e.g., may be the same or substantially the same as) the second transistor T12, the third transistor T13, the fourth transistor T14, and the fifth transistor T15 included in the first pixel circuit PXC1, respectively. In addition, the second transistor T92, the third transistor T93, the fourth transistor T94, and the fifth transistor T95 included in the ninth pixel circuit PXC9 may correspond to (e.g., may be the same or substantially the same as) the second transistor T12, the third transistor T13, the fourth transistor T14, and the fifth transistor T15 included in the first pixel circuit PXC1, respectively.

In addition, the second transistor T102, the third transistor T103, the fourth transistor T104, and the fifth transistor T105 included in the tenth pixel circuit PXC10 may correspond to (e.g., may be the same or substantially the same as) the second transistor T12, the third transistor T13, the fourth transistor T14, and the fifth transistor T15 included in the first pixel circuit PXC1, respectively. In addition, the second transistor T112, the third transistor T113, the fourth transistor T114, and the fifth transistor T115 included in the eleventh pixel circuit PXC11 may correspond to (e.g., may be the same or substantially the same as) the second transistor T12, the third transistor T13, the fourth transistor T14, and the fifth transistor T15 included in the first pixel circuit PXC1, respectively.

In addition, the second transistor T122, the third transistor T123, the fourth transistor T124, and the fifth transistor T125 included in the twelfth pixel circuit PXC12 may correspond to (e.g., may be the same or substantially the same as) the second transistor T12, the third transistor T13, the fourth transistor T14, and the fifth transistor T15 included in the first pixel circuit PXC1, respectively.

The first pixel PX1 may include a first well area W1 and a second well area W2. In an embodiment, the first well area W1 may have a rectangular shape in a plan view. However, the present disclosure is not limited thereto, and in another embodiment, the first well area W1 may have a shape different from the rectangular shape in a plan view.

The second well area W2 may be spaced apart from the first well area W1. In more detail, the second well area W2 may include a first portion W2A, a second portion W2B, and a third portion W2C. The first portion W2A may extend in the first direction DR1. In other words, the first portion W2A may have a rectangular shape (e.g., having long sides) extending in the first direction DR1 in a plan view. In addition, the first portion W2A may be spaced apart from the first well area W1 in the second direction DR2.

The second portion W2B may extend in the second direction DR2. In other words, the second portion W2B may have a rectangular shape (e.g., having long sides) extending in the second direction DR2 in a plan view. In addition, the second portion W2B may be spaced apart from the first well area W1 in a direction opposite to the first direction DR1.

The third portion W2C may be in contact with the first portion W2A and the second portion W2B. In an embodiment, the third portion W2C may have a rectangular shape in a plan view.

However, the present disclosure is not limited to the shape of the second well area W2 illustrated in FIGS. 3, 4, and 5, and in other embodiments, the second well area W2 may be spaced apart from the first well area W1, but may have a shape different from that illustrated in FIGS. 3, 4, and 5.

In an embodiment, a substrate (e.g., the substrate SUB of FIG. 6) to be described in more detail below may be a silicon substrate. In other words, the substrate may be a p-type silicon substrate or an n-type silicon substrate. In this case, each of the transistors placed on the substrate may have a metal-oxide-semiconductor field-effect transistor (hereinafter referred to as “MOSFET”) structure.

The MOSFET may be directly disposed on the substrate, and may be disposed in a well area (e.g., the first well area W1) or the like. In more detail, the MOSFET may be disposed on the well area. The well area may be a p-well (e.g., a p-type well) or an n-well (e.g., an n-type well) depending on the kind of the silicon substrate (e.g., n-type, p-type), the kind of the MOSFET, or the like.

In an embodiment, the first well area W1 may have a voltage higher than a voltage of the second well area W2. In other words, a concentration of impurities doped in the first well area W1 may be higher than a concentration of impurities doped in the second well area W2.

The second pixel PX2 may include a third well area W3 and a fourth well area W4. The third well area W3 may have a mirror image of the first well area W1 with respect to the first direction DR1. In more detail, the third well area W3 may have a structure corresponding to a mirror image of that of the first well area W1 with respect to a first virtual line VL1 extending between the first pixel PX1 and the second pixel PX2, and between the third pixel PX3 and the fourth pixel PX4.

In other words, the third well area W3 may have a rectangular shape in a plan view. However, the present disclosure is not limited thereto, and in another embodiment, the third well area W3 may have a shape different from the rectangular shape.

The fourth well area W4 may have a mirror image of the second well area W2 with respect to the first virtual line VL1.

In other words, the fourth well area W4 may be spaced apart from the third well area W3. In more detail, the fourth well area W4 may include a first portion W4A, a second portion W4B, and a third portion W4C. The first portion W4A may extend in the first direction DR1. In other words, the first portion W4A may have a rectangular shape extending in the first direction DR1 in a plan view. In addition, the first portion W4A may be spaced apart from the third well area W3 in a direction opposite to the second direction DR2.

The second portion W4B may extend in the second direction DR2. In other words, the second portion W4B may have a rectangular shape extending in the second direction DR2 in a plan view. In addition, the second portion W4B may be spaced apart from the third well area W3 in a direction opposite to the first direction DR1.

The third portion W4C may be in contact with the first portion W4A and the second portion W4B. In an embodiment, the third portion W4C may have a rectangular shape in a plan view.

However, the shape of the fourth well area W4 is not limited to that illustrated in FIGS. 3, 4, and 5, and in other embodiments, the fourth well area W4 may be spaced apart from the third well area W3, and may have a shape different from the illustrated shape.

The third well area W3 may have a voltage that is the same or substantially the same as the voltage of the first well area W1. In addition, the fourth well area W4 may have a voltage that is the same or substantially the same as the voltage of the second well area W2. In other words, the third well area W3 may have the voltage higher than the voltage of the fourth well area W4.

The third pixel PX3 may include a fifth well area W5 and a sixth well area W6. The fifth well area W5 may have a mirror image of the first well area W1 with respect to the second direction DR2. In more detail, the fifth well area W5 may have a structure corresponding to a mirror image of that of the first well area W1 with respect to a second virtual line VL2 extending between the first pixel PX1 and the third pixel PX3, and between the second pixel PX2 and the fourth pixel PX4.

In other words, the fifth well area W5 may have a rectangular shape in a plan view. However, the present disclosure is not limited thereto, and in another embodiment, the fifth well area W5 may have a shape different from the rectangular shape.

The sixth well area W6 may have a mirror image of the second well area W2 with respect to the second virtual line VL2.

In other words, the sixth well area W6 may be spaced apart from the fifth well area W5. In more detail, the sixth well area W6 may include a first portion W6A, a second portion W6B, and a third portion W6C. The first portion W6A may extend in the first direction DR1. In other words, the first portion W6A may have a rectangular shape extending in the first direction DR1 in a plan view. In addition, the first portion W6A may be spaced apart from the fifth well area W5 in the second direction DR2.

The second portion W6B may extend in the second direction DR2. In other words, the second portion W6B may have a rectangular shape extending in the second direction DR2 in a plan view. In addition, the second portion W6B may be spaced apart from the fifth well area W5 in the first direction DR1.

The third portion W6C may be in contact with the first portion W6A and the second portion W6B. In an embodiment, the third portion W6C may have a rectangular shape in a plan view.

However, the shape of the sixth well area W6 is not limited to that illustrated in FIGS. 3, 4, and 5, and in other embodiments, the sixth well area W6 may be spaced apart from the fifth well area W5, and may have a shape different from the illustrated shape.

The fifth well area W5 may have a voltage that is the same or substantially the same as the voltage of the first well area W1. In addition, the sixth well area W6 may have a voltage that is the same or substantially the same as the voltage of the second well area W2. In other words, the fifth well area W5 may have the voltage higher than the voltage of the sixth well area W6.

The fourth pixel PX4 may include a seventh well area W7 and an eighth well area W8. The seventh well area W7 may have a mirror image of the fifth well area W5 with respect to the first direction DR1. In more detail, the seventh well area W7 may have a structure corresponding to a mirror image of that of the fifth well area W5 with respect to the first virtual line VL1 extending between the first pixel PX1 and the second pixel PX2, and between the third pixel PX3 and the fourth pixel PX4.

In other words, the seventh well area W7 may have a rectangular shape in a plan view. However, the present disclosure is not limited thereto, and in another embodiment, the seventh well area W7 may have a shape different from the rectangular shape.

The eighth well area W8 may have a mirror image of the sixth well area W6 with respect to the first virtual line VL1.

In other words, the eighth well area W8 may be spaced apart from the seventh well area W7. In more detail, the eighth well area W8 may include a first portion W8A, a second portion W8B, and a third portion W8C. The first portion W8A may extend in the first direction DR1. In other words, the first portion W8A may have a rectangular shape extending in the first direction DR1 in a plan view. In addition, the first portion W8A may be spaced apart from the seventh well area W7 in a direction opposite to the second direction DR2.

The second portion W8B may extend in the second direction DR2. In other words, the second portion W8B may have a rectangular shape extending in the second direction DR2 in a plan view. In addition, the second portion W8B may be spaced apart from the seventh well area W7 in the first direction DR1.

The third portion W8C may be in contact with the first portion W8A and the second portion W8B. In an embodiment, the third portion W8C may have a rectangular shape in a plan view.

However, the shape of the eighth well area W8 is not limited to that illustrated in FIGS. 3, 4, and 5, and in other embodiments, the eighth well area W8 may be spaced apart from the seventh well area W7, and may have a shape different from the illustrated shape.

The seventh well area W7 may have a voltage that is the same or substantially the same as the voltage of the fifth well area W5. In addition, the eighth well area W8 may have a voltage that is the same or substantially the same as the voltage of the sixth well area W6. In other words, the seventh well area W7 may have the voltage higher than the voltage of the eighth well area W8.

Each of the first transistor T11 included in the first pixel circuit PXC1, the first transistor T21 included in the second pixel circuit PXC2, and the first transistor T31 included in the third pixel circuit PXC3 may be disposed in the first well area W1. In more detail, each of the first transistor T11 included in the first pixel circuit PXC1, the first transistor T21 included in the second pixel circuit PXC2, and the first transistor T31 included in the third pixel circuit PXC3 may be disposed on the first well area W1.

Each of the second transistor T12, the third transistor T13, the fourth transistor T14, and the fifth transistor T15 included in the first pixel circuit PXC1 may be disposed on the second well area W2. For example, each of the second transistor T12, the third transistor T13, the fourth transistor T14, and the fifth transistor T15 included in the first pixel circuit PXC1 may be disposed on the first portion W2A of the second well area W2.

However, the present disclosure is not limited thereto, and in another embodiment, each of the second transistor T12, the third transistor T13, the fourth transistor T14, and the fifth transistor T15 may be disposed on the second portion W2B of the second well area W2.

In another embodiment, some of the second transistor T12, the third transistor T13, the fourth transistor T14, and the fifth transistor T15 may be disposed on the first portion W2A of the second well area W2, and the others may be disposed on the second portion W2B of the second well area W2.

In other words, each of the second transistor T12, the third transistor T13, the fourth transistor T14, and the fifth transistor T15 may be disposed on the first portion W2A, the second portion W2B, or the third portion W2C.

Each of the second transistor T22, the third transistor T23, the fourth transistor T24, and the fifth transistor T25 included in the second pixel circuit PXC2 may be disposed on the second well area W2. For example, each of the second transistor T22, the third transistor T23, the fourth transistor T24, and the fifth transistor T25 included in the second pixel circuit PXC2 may be disposed on the first portion W2A of the second well area W2.

However, the present disclosure is not limited thereto, and in another embodiment, each of the second transistor T22, the third transistor T23, the fourth transistor T24, and the fifth transistor T25 may be disposed on the second portion W2B of the second well area W2.

In another embodiment, some of the second transistor T22, the third transistor T23, the fourth transistor T24, and the fifth transistor T25 may be disposed on the first portion W2A of the second well area W2, and the others may be disposed on the second portion W2B of the second well area W2.

In other words, each of the second transistor T22, the third transistor T23, the fourth transistor T24, and the fifth transistor T25 may be disposed on the first portion W2A, the second portion W2B, or the third portion W2C.

Each of the second transistor T32, the third transistor T33, the fourth transistor T34, and the fifth transistor T35 included in the third pixel circuit PXC3 may be disposed on the second well area W2. For example, some of the second transistor T32, the third transistor T33, the fourth transistor T34, and the fifth transistor T35 may be disposed on the second portion W2B of the second well area W2, and the others of the second transistor T32, the third transistor T33, the fourth transistor T34, and the fifth transistor T35 may be disposed on the third portion W2C of the second well area W2.

However, the present disclosure is not limited thereto, and in another embodiment, each of the second transistor T32, the third transistor T33, the fourth transistor T34, and the fifth transistor T35 may be disposed on the second portion W2B of the second well area W2.

In another embodiment, some of the second transistor T32, the third transistor T33, the fourth transistor T34, and the fifth transistor T35 may be disposed on the first portion W2A of the second well area W2, and the others may be disposed on the second portion W2B of the second well area W2.

In other words, each of the second transistor T32, the third transistor T33, the fourth transistor T34, and the fifth transistor T35 may be disposed on the first portion W2A, the second portion W2B, or the third portion W2C.

Each of the first transistor T41 included in the fourth pixel circuit PXC4, the first transistor T51 included in the fifth pixel circuit PXC5, and the first transistor T61 included in the sixth pixel circuit PXC6 may be disposed in the third well area W3. In more detail, each of the first transistor T41 included in the fourth pixel circuit PXC4, the first transistor T51 included in the fifth pixel circuit PXC5, and the first transistor T61 included in the sixth pixel circuit PXC6 may be disposed on the third well area W3.

Each of the second transistor T42, the third transistor T43, the fourth transistor T44, and the fifth transistor T45 included in the fourth pixel circuit PXC4 may be disposed on the fourth well area W4. For example, each of the second transistor T42, the third transistor T43, the fourth transistor T44, and the fifth transistor T45 included in the fourth pixel circuit PXC4 may be disposed on the first portion W4A of the fourth well area W4.

However, the present disclosure is not limited thereto, and in another embodiment, each of the second transistor T42, the third transistor T43, the fourth transistor T44, and the fifth transistor T45 included in the fourth pixel circuit PXC4 may be disposed on the second portion W4B of the fourth well area W4.

In another embodiment, some of the second transistor T42, the third transistor T43, the fourth transistor T44, and the fifth transistor T45 may be disposed on the first portion W4A of the fourth well area W4, and the others may be disposed on the second portion W4B of the fourth well area W4.

In other words, each of the second transistor T42, the third transistor T43, the fourth transistor T44, and the fifth transistor T45 may be disposed on the first portion W4A, the second portion W4B, or the third portion W4C.

Each of the second transistor T52, the third transistor T53, the fourth transistor T54, and the fifth transistor T55 included in the fifth pixel circuit PXC5 may be disposed on the fourth well area W4. For example, each of the second transistor T52, the third transistor T53, the fourth transistor T54, and the fifth transistor T55 included in the fifth pixel circuit PXC5 may be disposed on the first portion W4A of the fourth well area W4.

However, the present disclosure is not limited thereto, and in another embodiment, each of the second transistor T52, the third transistor T53, the fourth transistor T54, and the fifth transistor T55 included in the fifth pixel circuit PXC5 may be disposed on the second portion W4B of the fourth well area W4.

In another embodiment, some of the second transistor T52, the third transistor T53, the fourth transistor T54, and the fifth transistor T55 may be disposed on the first portion W4A of the fourth well area W4, and the others may be disposed on the second portion W4B of the fourth well area W4.

In other words, each of the second transistor T52, the third transistor T53, the fourth transistor T54, and the fifth transistor T55 may be disposed on the first portion W4A, the second portion W4B, or the third portion W4C.

Each of the second transistor T62, the third transistor T63, the fourth transistor T64, and the fifth transistor T65 included in the sixth pixel circuit PXC6 may be disposed on the fourth well area W4. For example, some of the second transistor T62, the third transistor T63, the fourth transistor T64, and the fifth transistor T65 included in the sixth pixel circuit PXC6 may be disposed on the second portion W4B of the fourth well area W4, and the others may be disposed on the third portion W4C of the fourth well area W4.

However, the present disclosure is not limited thereto, and in another embodiment, each of the second transistor T62, the third transistor T63, the fourth transistor T64, and the fifth transistor T65 included in the sixth pixel circuit PXC6 may be disposed on the second portion W4B of the fourth well area W4.

In another embodiment, some of the second transistor T62, the third transistor T63, the fourth transistor T64, and the fifth transistor T65 may be disposed on the first portion W4A of the fourth well area W4, and the others may be disposed on the second portion W4B of the fourth well area W4.

In other words, each of the second transistor T62, the third transistor T63, the fourth transistor T64, and the fifth transistor T65 may be disposed on the first portion W4A, the second portion W4B, or the third portion W4C.

Each of the first transistor T71 included in the seventh pixel circuit PXC7, the first transistor T81 included in the eighth pixel circuit PXC8, and the first transistor T91 included in the ninth pixel circuit PXC9 may be disposed in the fifth well area W5. In more detail, each of the first transistor T71 included in the seventh pixel circuit PXC7, the first transistor T81 included in the eighth pixel circuit PXC8, and the first transistor T91 included in the ninth pixel circuit PXC9 may be disposed on the fifth well area W5.

Each of the second transistor T72, the third transistor T73, the fourth transistor T74, and the fifth transistor T75 included in the seventh pixel circuit PXC7 may be disposed on the sixth well area W6. For example, each of the second transistor T72, the third transistor T73, the fourth transistor T74, and the fifth transistor T75 included in the seventh pixel circuit PXC7 may be disposed on the first portion W6A of the sixth well area W6.

However, the present disclosure is not limited thereto, and in another embodiment, each of the second transistor T72, the third transistor T73, the fourth transistor T74, and the fifth transistor T75 included in the seventh pixel circuit PXC7 may be disposed on the second portion W6B of the sixth well area W6.

In another embodiment, some of the second transistor T72, the third transistor T73, the fourth transistor T74, and the fifth transistor T75 may be disposed on the first portion W6A of the sixth well area W6, and the others may be disposed on the second portion W6B of the sixth well area W6.

In other words, each of the second transistor T72, the third transistor T73, the fourth transistor T74, and the fifth transistor T75 may be disposed on the first portion W6A, the second portion W6B, or the third portion W6C.

Each of the second transistor T82, the third transistor T83, the fourth transistor T84, and the fifth transistor T85 included in the eighth pixel circuit PXC8 may be disposed on the sixth well area W6. For example, each of the second transistor T82, the third transistor T83, the fourth transistor T84, and the fifth transistor T85 included in the eighth pixel circuit PXC8 may be disposed on the first portion W6A of the sixth well area W6.

However, the present disclosure is not limited thereto, and in another embodiment, each of the second transistor T82, the third transistor T83, the fourth transistor T84, and the fifth transistor T85 included in the eighth pixel circuit PXC8 may be disposed on the second portion W6B of the sixth well area W6.

In another embodiment, some of the second transistor T82, the third transistor T83, the fourth transistor T84, and the fifth transistor T85 may be disposed on the first portion W6A of the sixth well area W6, and the others may be disposed on the second portion W6B of the sixth well area W6.

In other words, each of the second transistor T82, the third transistor T83, the fourth transistor T84, and the fifth transistor T85 may be disposed on the first portion W6A, the second portion W6B, or the third portion W6C.

Each of the second transistor T92, the third transistor T93, the fourth transistor T94, and the fifth transistor T95 included in the ninth pixel circuit PXC9 may be disposed on the sixth well area W6. For example, some of the second transistor T92, the third transistor T93, the fourth transistor T94, and the fifth transistor T95 included in the ninth pixel circuit PXC9 may be disposed on the second portion W6B of the sixth well area W6, and the others may be disposed on the third portion W6C of the sixth well area W6.

However, the present disclosure is not limited thereto, and in another embodiment, each of the second transistor T92, the third transistor T93, the fourth transistor T94, and the fifth transistor T95 included in the ninth pixel circuit PXC9 may be disposed on the second portion W6B of the sixth well area W6.

In another embodiment, some of the second transistor T92, the third transistor T93, the fourth transistor T94, and the fifth transistor T95 may be disposed on the first portion W6A of the sixth well area W6, and the others may be disposed on the second portion W6B of the sixth well area W6.

In other words, each of the second transistor T92, the third transistor T93, the fourth transistor T94, and the fifth transistor T95 may be disposed on the first portion W6A, the second portion W6B, or the third portion W6C.

Each of the first transistor T101 included in the tenth pixel circuit PXC10, the first transistor T111 included in the eleventh pixel circuit PXC11, and the first transistor T121 included in the twelfth pixel circuit PXC12 may be disposed in the seventh well area W7. In more detail, each of the first transistor T101 included in the tenth pixel circuit PXC10, the first transistor T111 included in the eleventh pixel circuit PXC11, and the first transistor T121 included in the twelfth pixel circuit PXC12 may be disposed on the seventh well area W7.

Each of the second transistor T102, the third transistor T103, the fourth transistor T104, and the fifth transistor T105 included in the tenth pixel circuit PXC10 may be disposed on the eighth well area W8. For example, each of the second transistor T102, the third transistor T103, the fourth transistor T104, and the fifth transistor T105 included in the tenth pixel circuit PXC10 may be disposed on the first portion W8A of the eighth well area W8.

However, the present disclosure is not limited thereto, and in another embodiment, each of the second transistor T102, the third transistor T103, the fourth transistor T104, and the fifth transistor T105 included in the tenth pixel circuit PXC10 may be disposed on the second portion W8B of the eighth well area W8.

In another embodiment, some of the second transistor T102, the third transistor T103, the fourth transistor T104, and the fifth transistor T105 may be disposed on the first portion W8A of the eighth well area W8, and the others may be disposed on the second portion W8B of the eighth well area W8.

In other words, each of the second transistor T102, the third transistor T103, the fourth transistor T104, and the fifth transistor T105 may be disposed on the first portion W8A, the second portion W8B, or the third portion W8C.

Each of the second transistor T112, the third transistor T113, the fourth transistor T114, and the fifth transistor T115 included in the eleventh pixel circuit PXC11 may be disposed on the eighth well area W8. For example, each of the second transistor T112, the third transistor T113, the fourth transistor T114, and the fifth transistor T115 included in the eleventh pixel circuit PXC11 may be disposed on the first portion W8A of the eighth well area W8.

However, the present disclosure is not limited thereto, and in another embodiment, each of the second transistor T112, the third transistor T113, the fourth transistor T114, and the fifth transistor T115 included in the eleventh pixel circuit PXC11 may be disposed on the second portion W8B of the eighth well area W8.

In another embodiment, some of the second transistor T112, the third transistor T113, the fourth transistor T114, and the fifth transistor T115 may be disposed on the first portion W8A of the eighth well area W8, and the others may be disposed on the second portion W8B of the eighth well area W8.

In other words, each of the second transistor T112, the third transistor T113, the fourth transistor T114, and the fifth transistor T115 may be disposed on the first portion W8A, the second portion W8B, or the third portion W8C.

Each of the second transistor T122, the third transistor T123, the fourth transistor T124, and the fifth transistor T125 included in the twelfth pixel circuit PXC12 may be disposed on the eighth well area W8. For example, some of the second transistor T122, the third transistor T123, the fourth transistor T124, and the fifth transistor T125 included in the twelfth pixel circuit PXC12 may be disposed on the second portion W8B of the eighth well area W8, and the others may be disposed on the third portion W8C of the eighth well area W8.

However, the present disclosure is not limited thereto, and in another embodiment, each of the second transistor T122, the third transistor T123, the fourth transistor T124, and the fifth transistor T125 included in the eleventh pixel circuit PXC12 may be disposed on the second portion W8B of the eighth well area W8.

In another embodiment, some of the second transistor T122, the third transistor T123, the fourth transistor T124, and the fifth transistor T125 may be disposed on the first portion W8A of the eighth well area W8, and the others may be disposed on the second portion W8B of the eighth well area W8.

In other words, each of the second transistor T122, the third transistor T123, the fourth transistor T124, and the fifth transistor T125 may be disposed on the first portion W8A, the second portion W8B, or the third portion W8C.

The first well area W1, the third well area W3, the fifth well area W5, and the seventh well area W7 may be high-voltage well areas. High voltage transistors may be disposed on the high voltage well areas. For example, the driving transistors may be disposed on the high voltage well areas. The driving transistors may include a plurality of first transistors T11, T21, T31, T41, T51, T61, T71, T81, T91, T101, T111, and T121.

The second well area W2, the fourth well area W4, the sixth well area W6, and the eighth well area W8 may be low-voltage well areas. Low voltage transistors may be disposed on the low voltage well areas. For example, a plurality of transistors except for the driving transistors may be disposed on the low voltage well areas.

Accordingly, the high voltage transistors and the low voltage transistors may be disposed separately from each other. For example, because the first well area W1 is spaced apart from the second well area W2, the high-voltage transistors and the low-voltage transistors may be disposed separately from each other. In addition, a plurality of transistors may be disposed adjacent to each other on a designated well area. As such, an interval between the pixels may be reduced (e.g., may be narrowed). Accordingly, a resolution of the display device (e.g., the display device DD of FIG. 1) may be improved.

FIG. 6 is a schematic cross-sectional view of the display device taken along the X-Y line of FIG. 4. In more detail, FIG. 6 is a schematic cross-sectional view illustrating structures of a first transistor (e.g., the first transistor T31) included in a third pixel circuit, and a second transistor (e.g., the second transistor T12) included in a first pixel circuit.

Referring to FIGS. 4 and 6, a substrate SUB may be a silicon substrate. In other words, the substrate SUB may be a p-type silicon substrate or an n-type silicon substrate. In this case, p may refer to a hole, and n may refer to an electron. The substrate SUB may include the first well area W1, and the first portion W2A, the second portion W2B, and the third portion W2C of the second well area W2. Hereinafter, the first well area W1 and the first portion W2A of the second well area W2 will be mainly described in more detail.

The first well area W1 may be a p-well or an n-well depending on a type of the first transistor T31 included in the third pixel circuit (e.g., the third pixel circuit PXC3 of FIG. 5) and a type of the silicon substrate. In addition, the first portion W2A of the second well area W2 may be a p-well or an n-well depending on a type of the second transistor T12 included in the first pixel circuit (e.g., the first pixel circuit PXC1 of FIG. 5) and a type of the silicon substrate.

In an embodiment, a height of the first well area W1 in the third direction DR3 may be greater than a height of the first portion W2A of the second well area W2 in the third direction DR3. This may be because the first transistor T31 disposed on the first well area W1 is a high voltage transistor, and a height of the well area may be increased to withstand a high voltage of the high voltage transistor.

The substrate SUB may include a second source area SA2 and a second drain area DA2. For example, the second source area SA2 and the second drain area DA2 may be an n-source area and an n-drain area, respectively. However, the present disclosure is not limited thereto, and the second source area SA2 and the second drain area DA2 may be a p-source area and a p-drain area, respectively.

A gate insulating layer GI may be disposed on the substrate SUB. The gate insulating layer GI may include an inorganic material, such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), or the like. These materials may be used alone or in a suitable combination with each other.

The first gate electrode GE1 and the second gate electrode GE2 may be disposed on the gate insulating layer GI. Each of the first gate electrode GE1 and the second gate electrode GE2 may include a metal, an alloy metal nitride, a conductive metal oxide, a transparent conductive material, or the like.

Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in a suitable combination with each other.

In addition, examples of the conductive metal oxide may include Indium tin oxide, indium zinc oxide, or the like. These materials may be used alone or in a suitable combination with each other.

In addition, examples of the metal nitride may include aluminum nitride (“AlNₓ”), tungsten nitride (“WNₓ”), chromium nitride (“CrNₓ”), or the like. These materials may be used alone or in a suitable combination with each other.

A gate spacer GS may be disposed on the substrate SUB. In more detail, the gate spacer GS may be disposed at opposite sides of the first gate electrode GE1, the gate insulating layer GI, and the second gate electrode GE2. The gate spacer GS may serve to space apart (e.g., separate) the first gate electrode GE1 from the first source area SA1 and the first drain area DA1. In addition, the gate spacer GS may serve to space apart (e.g., separate) the second gate electrode GE2 from the second source area SA2 and the second drain area DA2.

An insulating layer IL may be disposed on the substrate SUB. The insulating layer IL may cover (e.g., may sufficiently cover) the gate electrodes GE1 and GE2. For example, the insulating layer IL may include one or more inorganic materials, such as silicon oxide, silicon nitride, silicon carbide, silicon oxynitride, silicon oxycarbide, or the like. These materials may be used alone or in a suitable combination with each other.

The first source electrode SE1 and the first drain electrode DE1 may be disposed on the insulating layer IL. The first source electrode SE1 may be connected to the first source area SA1 through a contact hole penetrating the insulating layer IL. In addition, the first drain electrode DE1 may be connected to the first drain area DA1 through a contact hole penetrating the insulating layer IL.

The second source electrode SE2 and the second drain electrode DE2 may be disposed on the insulating layer IL. The second source electrode SE2 may be connected to the second source area SA2 through a contact hole penetrating the insulating layer IL. In addition, the second drain electrode DE2 may be connected to the second drain area DA2 through a contact hole penetrating the insulating layer IL.

The passivation layer PVX may be disposed on the insulating layer IL. The passivation layer PVX may cover (e.g., may sufficiently cover) the first source electrode SE1, the second source electrode SE2, the first drain electrode DE1, and the second drain electrode DE2.

The passivation layer PVX may include an inorganic insulating material. Examples of the inorganic material may include silicon oxide, silicon nitride, silicon oxynitride, or the like. These materials may be used alone or in a suitable combination with each other.

A via insulating layer VIA may be disposed on the passivation layer PVX. The via insulating layer VIA may include an organic material. For example, the via insulating layer VIA may include one or more organic materials, such as a phenolic resin, an acrylic resin, a polyimide resin, a polyamide resin, a siloxane resin, an epoxy resin, or the like. These materials may be used alone or in a suitable combination with each other.

The first transistor T31 may be a MOSFET including the first source area SA1, the first source electrode SE1, the first gate electrode GE1, the first drain area DA1, and the first drain electrode DE1. In addition, the second transistor T12 may be a MOSFET including the second source area SA2, the second source electrode SE2, the second gate electrode GE2, the second drain area DA2, and the second drain electrode DE2.

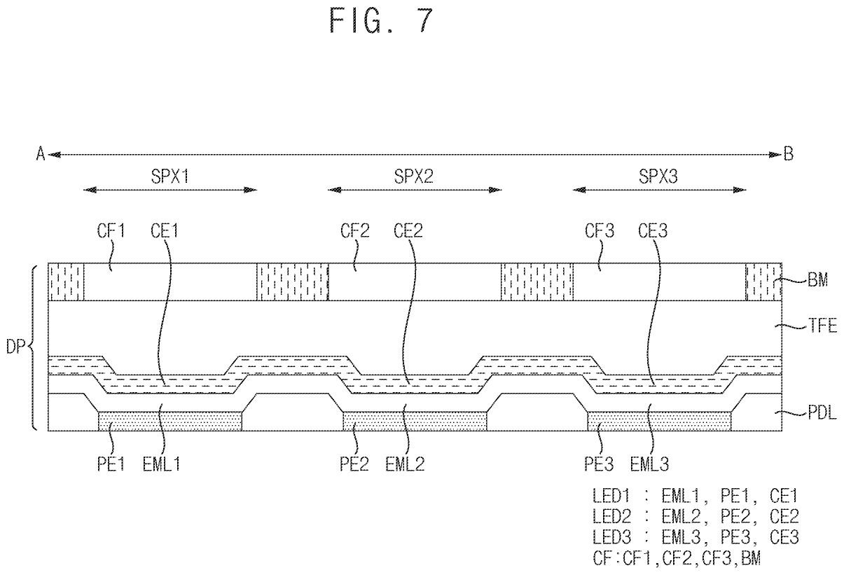

FIG. 7 is a schematic cross-sectional view of the display device taken along the A-B line of FIG. 5. In more detail, FIG. 7 is a schematic cross-sectional view illustrating a display unit included in a display device.

Referring to FIGS. 5 and 7, the display unit (e.g., a display layer) DP may be disposed on the substrate (e.g., the substrate SUB of FIG. 6). The display unit DP may include a first light emitting element LED1, a second light emitting element LED2, a third light emitting element LED3, a pixel defining layer PDL, an encapsulation layer TFE, and a color filter layer CF.

Each of the first light emitting element LED1, the second light emitting element LED2, and the third light emitting element LED3 may correspond to the light emitting element EE of FIG. 2 of a corresponding sub-pixel. The first light emitting element LED1 may be electrically connected to the first transistor T11, the second transistor T12, the third transistor T13, the fourth transistor T14, and the fifth transistor T15 of the first pixel circuit PXC1.

In addition, the second light emitting element LED2 may be electrically connected to the first transistor T21, the second transistor T22, the third transistor T23, the fourth transistor T24, and the fifth transistor T25 of the second pixel circuit PXC2. In addition, the third light emitting element LED3 may be electrically connected to the first transistor T31, the second transistor T32, the third transistor T33, the fourth transistor T34, and the fifth transistor T35 of the third pixel circuit PXC3.

The first light emitting element LED1 may include a first pixel electrode PE1, a first light emitting layer EML1, and a first common electrode CE1. The first pixel electrode PE1 may include a metal, an alloy, a conductive metal oxide, a transparent conductive material, or the like. These materials may be used alone or in a suitable combination with each other. The first pixel electrode PE1 may operate as an anode.

The pixel defining layer PDL may cover opposite side portions of each of the first pixel electrode PE1, the second pixel electrode PE2, and the third pixel electrode PE3. In addition, an opening that exposes a portion of an upper surface of each of the first pixel electrode PE1, the second pixel electrode PE2, and the third pixel electrode PE3 may be defined in the pixel defining layer PDL.

For example, the pixel defining layer PDL may include an inorganic material or an organic material. In an embodiment, the pixel defining layer PDL may include an organic material, such as an epoxy resin or a siloxane resin. These materials may be used alone or in a suitable combination with each other. In another embodiment, the pixel defining layer PDL may further include a light blocking material containing a black pigment, a black dye, or the like.

The first light emitting layer EML1 may be disposed on the first pixel electrode PE1. The first light emitting layer EML1 may include an organic material that emits light of a desired color (e.g., a predetermined color). The first light emitting layer EML1 may further include at least one of a hole injection layer, a hole transport layer, or an electron injection layer.

The first common electrode CE1 may be disposed on the first light emitting layer EML1. The first common electrode CE1 may include a metal, an alloy, a metal nitride, a conductive metal oxide, a transparent conductive material, or the like. These materials may be used alone or in a suitable combination with each other. The first common electrode CE1 may operate as a cathode.

The second light emitting element LED2 may include a second light emitting layer EML2, a second pixel electrode PE2, and a second common electrode CE2. The second light emitting layer EML2 may include the same or substantially the same material as that of the first light emitting layer EML1. In addition, the second pixel electrode PE2 may include the same or substantially the same material as that of the first pixel electrode PE1. Further, the second common electrode CE2 may include the same or substantially the same material as that of the first common electrode CE1.

The third light emitting element LED3 may include a third light emitting layer EML3, a third pixel electrode PE3, and a third common electrode CE3. The third light emitting layer EML3 may include the same or substantially the same material as that of the first light emitting layer EML1. In addition, the third pixel electrode PE3 may include the same or substantially the same material as that of the first pixel electrode PE1. Further, the third common electrode CE3 may include the same or substantially the same material as that of the first common electrode CE1.

In an embodiment, the first light emitting layer EML1, the second light emitting layer EML2, and the third light emitting layer EML3 may be connected to each other. In other words, the first light emitting layer EML1, the second light emitting layer EML2, and the third light emitting layer EML3 may constitute one light emitting layer (e.g., may be one integral layer). However, the present disclosure is not limited thereto, and in other embodiments, the first light emitting layer EML1, the second light emitting layer EML2, and the third light emitting layer EML3 may be spaced apart (e.g., separated) from each other.

In an embodiment, the first common electrode CE1, the second common electrode CE2, and the third common electrode CE3 may be connected to each other. In other words, the first common electrode CE1, the second common electrode CE2, and the third common electrode CE3 may constitute one common electrode (e.g., may be one integral layer). However, the present disclosure is not limited thereto, and in other embodiments, the first common electrode CE1, the second common electrode CE2, and the third common electrode CE3 may be spaced apart (e.g., separated) from each other.

The encapsulation layer TFE may be disposed on the first common electrode CE1, the second common electrode CE2, and the third common electrode CE3. The encapsulation layer TFE may include at least one inorganic encapsulation layer, and at least one organic encapsulation layer. For example, the inorganic encapsulation layer and the organic encapsulation layer may be alternately stacked with each other.

The color filter layer CF may be disposed on the encapsulation layer TFE. The color filter layer CF may include a light blocking part BM, a first color filter CF1, a second color filter CF2, and a third color filter CF3.

The light blocking part BM may define an area of each of the first sub-pixel SPX1, the second sub-pixel SPX2, and the third sub-pixel SPX3. In other words, the light blocking part BM may define openings defining regions of each of the first sub-pixel SPX1, the second sub-pixel SPX2, and the third sub-pixel SPX3. Accordingly, the light blocking part BM may not overlap with regions of the first sub-pixel SPX1, the second sub-pixel SPX2, and the third sub-pixel SPX3. In an embodiment, the light blocking part BM may include an organic material and/or an inorganic material containing a black pigment, a black dye, or the like.

The first color filter CF1, the second color filter CF2, and the third color filter CF3 may be disposed in the openings defined by the light blocking part BM, respectively.

The first color filter CF1 may be disposed to overlap with an area of the first sub-pixel SPX1. The first color filter CF1 may transmit only light having a specific wavelength of the light emitted from the first light emitting element LED1.

The second color filter CF2 may be disposed to overlap with an area of the second sub-pixel SPX2. The second color filter CF2 may transmit only light having a specific wavelength of the light emitted from the second light emitting element LED2.

The third color filter CF3 may be disposed to overlap with an area of the third sub-pixel SPX3. The third color filter CF3 may transmit only light having a specific wavelength of the light emitted from the third light emitting element LED3.

In FIG. 7, the color filter layer CF may include the light blocking part BM, the first color filter CF1, the second color filter CF2, and the third color filter CF3, but the present disclosure is not limited thereto. For example, the color filter layer CF may further include a reflection part or a low refractive layer.

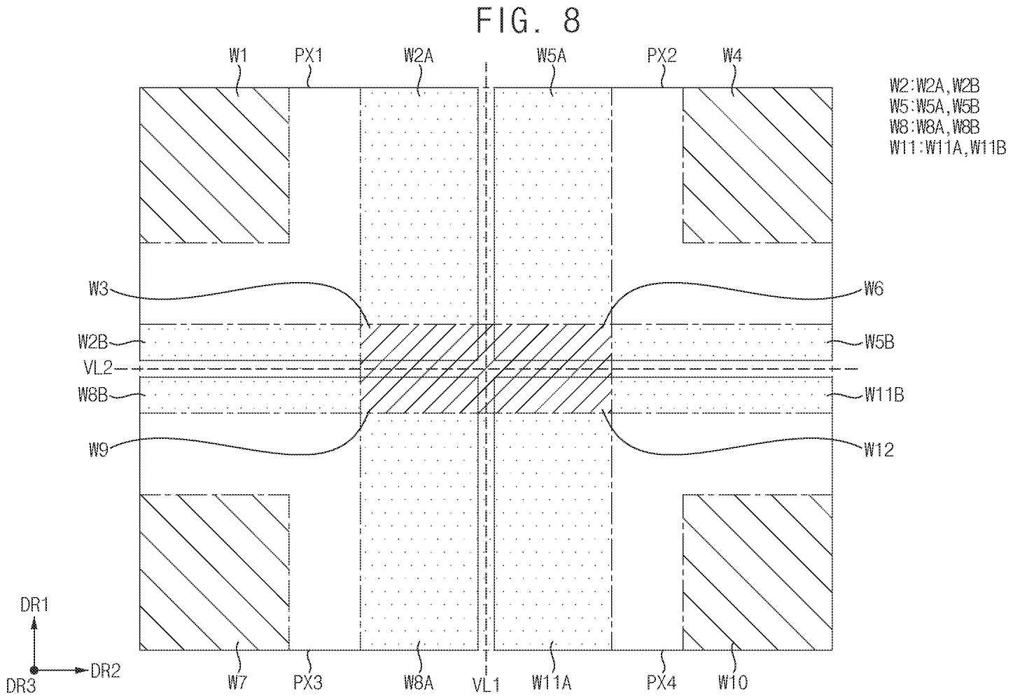

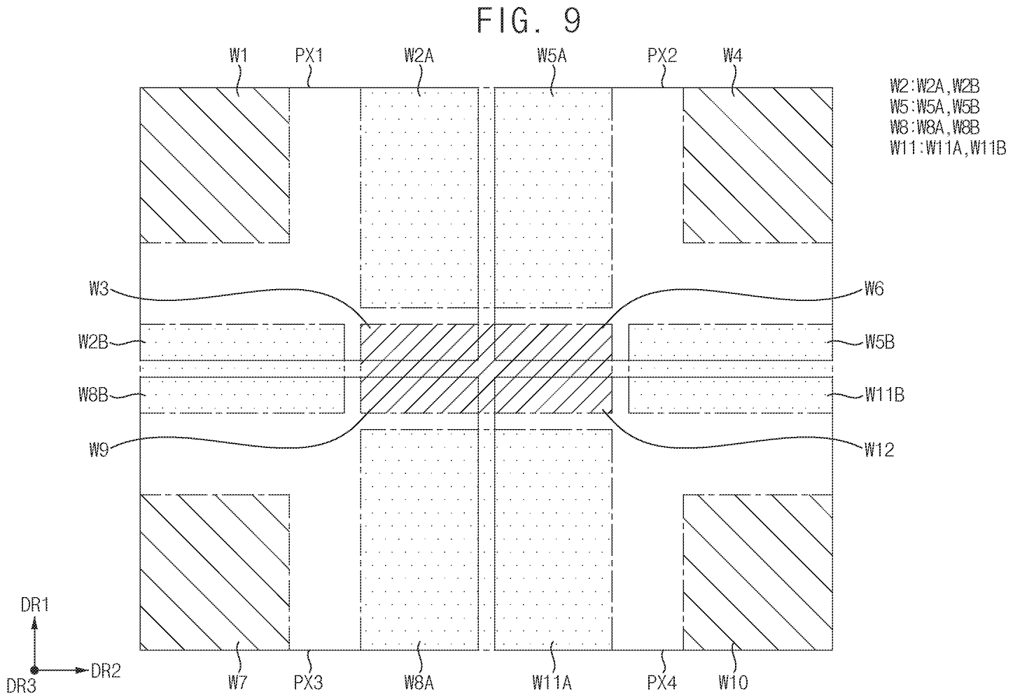

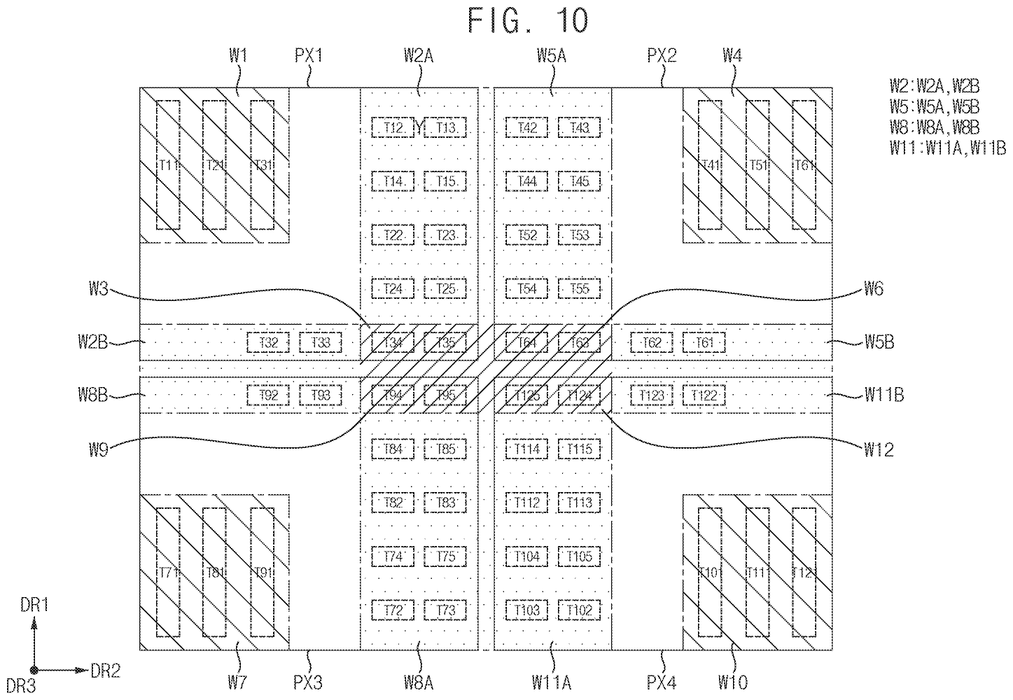

FIG. 8 is a schematic plan view illustrating a plurality of wells included in a display device according to an embodiment. FIG. 9 is a schematic plan view illustrating a plurality of wells included in a display device according to an embodiment. FIG. 10 is a schematic plan view illustrating a plurality of wells and transistors included in the display device of FIG. 8.

Redundant description of the components illustrated in FIGS. 8, 9, and 10 that are the same or substantially the same as those of the display device described above with reference to FIGS. 3, 4, and 5 may not be repeated.

Referring to FIG. 8, a first pixel PX1 may include a first well area W1, a second well area W2, and a third well area W3. In an embodiment, the first well area W1 may have a rectangular shape in a plan view. However, the present disclosure is not limited thereto, and in another embodiment, the first well area W1 may have a shape different from the rectangular shape in a plan view.

The second well area W2 may be spaced apart from the first well area W1. In more detail, the second well area W2 may include a first portion W2A and a second portion W2B. The first portion W2A may extend in the first direction DR1. In other words, the first portion W2A may have a rectangular shape extending in the first direction DR1 in a plan view. In addition, the first portion W2A may be spaced apart from the first well area W1 in the second direction DR2.

The second portion W2B may extend in the second direction DR2. In other words, the second portion W2B may have a rectangular shape extending in the second direction DR2 in a plan view. In addition, the second portion W2B may be spaced apart from the first well area W1 in a direction opposite to the first direction DR1.

However, the present disclosure is not limited to the shape of the second well area W2 illustrated in FIG. 8, and in another embodiment, the second well area W2 may be spaced apart from the first well area W1, and may have a shape different from the illustrated shape.

As illustrated in FIGS. 8 and 10, the third well area W3 may be in contact with the first portion W2A and the second portion W2B. In an embodiment, the third well area W3 may have a rectangular shape in a plan view. However, the present disclosure is not limited thereto, and the third well area W3 may have a shape different from the rectangular shape in a plan view.

In an embodiment, the first well area W1 may have a voltage higher than a voltage of the second well area W2. In addition, the first well area W1 may have the voltage higher than a voltage of the third well area W3. In addition, the second well area W2 may have the voltage different from the voltage of the third well area W3. For example, the second well area W2 may have the voltage higher than the voltage of the third well area W3. However, the present disclosure is not limited thereto, and in another embodiment, the second well area W2 may have the voltage lower than the voltage of the third well area W3.

A second pixel PX2 may include a fourth well area W4, a fifth well area W5, and a sixth well area W6. The fourth well area W4 may have a mirror image of the first well area W1 with respect to the first direction DR1. In more detail, the fourth well area W4 may have a structure corresponding to a mirror image of that of the first well area W1 with respect to a first virtual line VL1 extending between the first pixel PX1 and the second pixel PX2, and between the third pixel PX3 and the fourth pixel PX4.

The fifth well area W5 may have a mirror image of the second well area W2 with respect to the first virtual line VL1. In addition, the sixth well area W6 may have a mirror image of the third well area W3 with respect to the first virtual line VL1.

In an embodiment, the fourth well area W4 may have a voltage equal to or substantially equal to the voltage of the first well area W1. In addition, the fifth well area W5 may have a voltage equal to or substantially equal to the voltage of the second well area W2. Further, the sixth well area W6 may have a voltage equal to or substantially equal to the voltage of the third well area W3.

A third pixel PX3 may include a seventh well area W7, an eighth well area W8, and a ninth well area W9. The seventh well area W7 may have a mirror image of the first well area W1 with respect to the second direction DR2. In more detail, the seventh well area W7 may have a structure corresponding to a mirror image of that of the first well area W1 with respect to a second virtual line VL2 extending between the first pixel PX1 and the third pixel PX3, and between the second pixel PX2 and the fourth pixel PX4.

The eighth well area W8 may have a mirror image of the second well area W2 with respect to the second virtual line VL2. In addition, the ninth well area W9 may have a mirror image of the third well area W3 with respect to the second virtual line VL2.

In an embodiment, the seventh well area W7 may have a voltage equal to or substantially equal to the voltage of the first well area W1. In addition, the eighth well area W8 may have a voltage equal to or substantially equal to the voltage of the second well area W2. In addition, the ninth well area W9 may have a voltage equal to or substantially equal to the voltage of the third well area W3.

A fourth pixel PX4 may include a tenth well area W10, an eleventh well area W11, and a twelfth well area W12. The tenth well area W10 may have a mirror image of the seventh well area W7 with respect to the first direction DR1. In more detail, the tenth well area W10 may have a structure corresponding to a mirror image of that of the seventh well area W7 with respect to the first virtual line VL1.

The eleventh well area W11 may have a mirror image of the eighth well area W8 with respect to the first virtual line VL1. In addition, the twelfth well area W12 may have a mirror image of the ninth well area W9 with respect to the first virtual line VL1.

In an embodiment, the tenth well area W10 may have a voltage equal to or substantially equal to the voltage of the seventh well area W7. In addition, the eleventh well area W11 may have a voltage equal to or substantially equal to the voltage of the eighth well area W8. In addition, the twelfth well area W12 may have a voltage equal to or substantially equal to the voltage of the ninth well area W9.

Referring to FIG. 9, in another embodiment, the first portion W2A of the second well area W2 and the third well area W3 may be spaced apart (e.g., separated) from each other. In addition, the first portion W5A of the fifth well area W5 and the sixth well area W6 may be spaced apart (e.g., separated) from each other. In addition, the second portion W2B of the second well area W2 and the third well area W3 may be spaced apart (e.g., separated) from each other. In addition, the second portion W8B of the eighth well area W8 and the ninth well area W9 may be spaced apart (e.g., separated) from each other. In addition, the second portion W5B of the fifth well area W5 and the sixth well area W6 may be spaced apart (e.g., separated) from each other. In addition, the second portion W11B of the eleventh well area W11 and the twelfth well area W12 may be spaced apart (e.g., separated) from each other. In addition, the first portion W8A of the eighth well area W8 and the ninth well area W9 may be spaced apart (e.g., separated) from each other. In addition, the first portion W11A of the eleventh well area W11 and the twelfth well area W12 may be spaced apart (e.g., separated) from each other.

Referring to FIG. 10, each of the first transistor T11 included in the first pixel circuit PXC1, the first transistor T21 included in the second pixel circuit PXC2, and the first transistor T31 included in the third pixel circuit PXC3 may be disposed in the first well area W1. In more detail, each of the first transistor T11 included in the first pixel circuit PXC1, the first transistor T21 included in the second pixel circuit PXC2, and the first transistor T31 included in the third pixel circuit PXC3 may be disposed on the first well area W1.

Each of the second transistor T12, the third transistor T13, the fourth transistor T14, and the fifth transistor T15 included in the first pixel circuit PXC1 may be disposed on the second well area W2 or the third well area W3. For example, each of the second transistor T12, the third transistor T13, the fourth transistor T14, and the fifth transistor T15 included in the first pixel circuit PXC1 may be disposed on the first portion W2A of the second well area W2. However, the present disclosure is not limited thereto, and in another embodiment, each of the second transistor T12, the third transistor T13, the fourth transistor T14, and the fifth transistor T15 included in the first pixel circuit PXC1 may be disposed on the second portion W2B of the second well area W2. In another embodiment, some of the second transistor T12, the third transistor T13, the fourth transistor T14, and the fifth transistor T15 may be disposed on the first portion W2A of the second well area W2, and the others may be disposed on the third well area W3.

Each of the second transistor T22, the third transistor T23, the fourth transistor T24, and the fifth transistor T25 included in the second pixel circuit PXC2 may be disposed on the second well area W2 or the third well area W3. For example, each of the second transistor T22, the third transistor T23, the fourth transistor T24, and the fifth transistor T25 included in the second pixel circuit PXC2 may be disposed on the first portion W2A of the second well area W2. However, the present disclosure is not limited thereto, and in another embodiment, each of the second transistor T22, the third transistor T23, the fourth transistor T24, and the fifth transistor T25 included in the second pixel circuit PXC2 may be disposed on the second portion W2B of the second well area W2. In another embodiment, some of the second transistor T22, the third transistor T23, the fourth transistor T24, and the fifth transistor T25 may be disposed on the first portion W2A of the second well area W2, and the others may be disposed on the third well area W3.

Each of the second transistor T32, the third transistor T33, the fourth transistor T34, and the fifth transistor T35 included in the third pixel circuit PXC3 may be disposed on the second well area W2 or the third well area W3. For example, some of the second transistor T32, the third transistor T33, the fourth transistor T34, and the fifth transistor T35 may be disposed on the second portion W2B of the second well area W2, and the others may be disposed on the third well area W3. However, the present disclosure is not limited thereto, and in another embodiment, each of the second transistor T32, the third transistor T33, the fourth transistor T34, and the fifth transistor T35 included in the third pixel circuit PXC3 may be disposed on the second portion W2B of the second well area W2. In another embodiment, some of the second transistor T32, the third transistor T33, the fourth transistor T34, and the fifth transistor T35 may be disposed on the first portion W2A of the second well area W2, and the others may be disposed on the second portion W2B of the second well area W2.

Each of the first transistor T41 included in the fourth pixel circuit PXC4, the first transistor T51 included in the fifth pixel circuit PXC5, and the first transistor T61 included in the sixth pixel circuit PXC6 may be disposed in the fourth well area W4. In more detail, each of the first transistor T41 included in the fourth pixel circuit PXC4, the first transistor T51 included in the fifth pixel circuit PXC5, and the first transistor T61 included in the sixth pixel circuit PXC6 may be disposed on the fourth well area W4.

Each of the second transistor T42, the third transistor T43, the fourth transistor T44, and the fifth transistor T45 included in the fourth pixel circuit PXC4 may be disposed on the fifth well area W5 or the sixth well area W6. For example, each of the second transistor T42, the third transistor T43, the fourth transistor T44, and the fifth transistor T45 included in the fourth pixel circuit PXC4 may be disposed on the first portion W5A of the fifth well area W5. However, the present disclosure is not limited thereto, and in another embodiment, each of the second transistor T42, the third transistor T43, the fourth transistor T44, and the fifth transistor T45 included in the fourth pixel circuit PXC4 may be disposed on the second portion W5B of the fifth well area W5. In another embodiment, some of the second transistor T42, the third transistor T43, the fourth transistor T44, and the fifth transistor T45 may be disposed on the first portion W5A of the fifth well area W5, and the others may be disposed on the sixth well area W6.

Each of the second transistor T52, the third transistor T53, the fourth transistor T54, and the fifth transistor T55 included in the fifth pixel circuit PXC5 may be disposed on the fifth well area W5 or the sixth well area W6. For example, each of the second transistor T52, the third transistor T53, the fourth transistor T54, and the fifth transistor T55 included in the fifth pixel circuit PXC5 may be disposed on the first portion W5A of the fifth well area W5. However, the present disclosure is not limited thereto, and in another embodiment, each of the second transistor T52, the third transistor T53, the fourth transistor T54, and the fifth transistor T55 included in the fifth pixel circuit PXC5 may be disposed on the second portion W5B of the fifth well area W5. In another embodiment, some of the second transistor T52, the third transistor T53, the fourth transistor T54, and the fifth transistor T55 may be disposed on the first portion W5A of the fifth well area W5, and the others may be disposed on the sixth well area W6.

Each of the second transistor T62, the third transistor T63, the fourth transistor T64, and the fifth transistor T65 included in the sixth pixel circuit PXC6 may be disposed on the fifth well area W5 or the sixth well area W6. For example, some of the second transistor T62, the third transistor T63, the fourth transistor T64, and the fifth transistor T65 may be disposed on the second portion W5B of the fifth well area W5, and the others may be disposed on the sixth well area W6. However, the present disclosure is not limited thereto, and in another embodiment, each of the second transistor T62, the third transistor T63, the fourth transistor T64, and the fifth transistor T65 included in the sixth pixel circuit PXC6 may be disposed on the second portion W5B of the fifth well area W5. In another embodiment, some of the second transistor T62, the third transistor T63, the fourth transistor T64, and the fifth transistor T65 may be disposed on the first portion W5A of the fifth well area W5, and the others may be disposed on the sixth well area W6.

Each of the first transistor T71 included in the seventh pixel circuit PXC7, the first transistor T81 included in the eighth pixel circuit PXC8, and the first transistor T91 included in the ninth pixel circuit PXC9 may be disposed in the seventh well area W7. In more detail, each of the first transistor T71 included in the seventh pixel circuit PXC7, the first transistor T81 included in the eighth pixel circuit PXC8, and the first transistor T91 included in the ninth pixel circuit PXC9 may be disposed on the seventh well area W7.

Each of the second transistor T72, the third transistor T73, the fourth transistor T74, and the fifth transistor T75 included in the seventh pixel circuit PXC7 may be disposed on the eighth well area W8 or the ninth well area W9. For example, each of the second transistor T72, the third transistor T73, the fourth transistor T74, and the fifth transistor T75 included in the seventh pixel circuit PXC7 may be disposed on the first portion W8A of the eighth well area W8. However, the present disclosure is not limited thereto, and in another embodiment, each of the second transistor T72, the third transistor T73, the fourth transistor T74, and the fifth transistor T75 included in the seventh pixel circuit PXC7 may be disposed on the second portion W8B of the eighth well area W8. In another embodiment, some of the second transistor T72, the third transistor T73, the fourth transistor T74, and the fifth transistor T75 may be disposed on the first portion W8A of the eighth well area W8, and the others may be disposed on the ninth well area W9.

Each of the second transistor T82, the third transistor T83, the fourth transistor T84, and the fifth transistor T85 included in the eighth pixel circuit PXC8 may be disposed on the eighth well area W8 or the ninth well area W9. For example, each of the second transistor T82, the third transistor T83, the fourth transistor T84, and the fifth transistor T85 included in the eighth pixel circuit PXC8 may be disposed on the first portion W8A of the eighth well area W8. However, the present disclosure is not limited thereto, and in another embodiment, each of the second transistor T82, the third transistor T83, the fourth transistor T84, and the fifth transistor T85 included in the eighth pixel circuit PXC8 may be disposed on the second portion W8B of the eighth well area W8. In another embodiment, some of the second transistor T82, the third transistor T83, the fourth transistor T84, and the fifth transistor T85 may be disposed on the first portion W8A of the eighth well area W8, and the others may be disposed on the ninth well area W9.

Each of the second transistor T92, the third transistor T93, the fourth transistor T94, and the fifth transistor T95 included in the ninth pixel circuit PXC9 may be disposed on the eighth well area W8 or the ninth well area W9. For example, some of the second transistor T92, the third transistor T93, the fourth transistor T94, and the fifth transistor T95 may be disposed on the second portion W8B of the eighth well area W8, and the others may be disposed on the ninth well area W9. However, the present disclosure is not limited thereto, and in another embodiment, each of the second transistor T92, the third transistor T93, the fourth transistor T94, and the fifth transistor T95 included in the ninth pixel circuit PXC9 may be disposed on the second portion W8B of the eighth well area W8. In another embodiment, some of the second transistor T92, the third transistor T93, the fourth transistor T94, and the fifth transistor T95 may be disposed on the first portion W8A of the eighth well area W8, and the others may be disposed on the ninth well area W9.

Each of the first transistor T101 included in the tenth pixel circuit PXC10, the first transistor T111 included in the eleventh pixel circuit PXC11, and the first transistor T121 included in the twelfth pixel circuit PXC12 may be disposed in the tenth well area W10. In more detail, each of the first transistor T101 included in the tenth pixel circuit PXC10, the first transistor T111 included in the eleventh pixel circuit PXC11, and the first transistor T121 included in the twelfth pixel circuit PXC12 may be disposed on the tenth well area W10.

Each of the second transistor T102, the third transistor T103, the fourth transistor T104, and the fifth transistor T105 included in the tenth pixel circuit PXC10 may be disposed on the eleventh well area W11 or the twelfth well area W12. For example, each of the second transistor T102, the third transistor T103, the fourth transistor T104, and the fifth transistor T105 included in the tenth pixel circuit PXC10 may be disposed on the first portion W11A of the eleventh well area W11. However, the present disclosure is not limited thereto, and in another embodiment, each of the second transistor T102, the third transistor T103, the fourth transistor T104, and the fifth transistor T105 included in the tenth pixel circuit PXC10 may be disposed on the second portion W11B of the eleventh well area W11. In another embodiment, some of the second transistor T102, the third transistor T103, the fourth transistor T104, and the fifth transistor T105 may be disposed on the first portion W11A of the eleventh well area W11, and the others may be disposed on the twelfth well area W12.

Each of the second transistor T112, the third transistor T113, the fourth transistor 114, and the fifth transistor T115 included in the eleventh pixel circuit PXC11 may be disposed on the eleventh well area W11 or the twelfth well area W12. For example, each of the second transistor T112, the third transistor T113, the fourth transistor T114, and the fifth transistor T115 included in the eleventh pixel circuit PXC11 may be disposed on the first portion W11A of the eleventh well area W11. However, the present disclosure is not limited thereto, and in another embodiment, each of the second transistor T112, the third transistor T113, the fourth transistor T114, and the fifth transistor T115 included in the eleventh pixel circuit PXC11 may be disposed on the second portion W11B of the eleventh well area W11. In another embodiment, some of the second transistor T112, the third transistor T113, the fourth transistor T114, and the fifth transistor T115 may be disposed on the first portion W11A of the eleventh well area W11, and the others may be disposed on the twelfth well area W12.

Each of the second transistor T122, the third transistor T123, the fourth transistor T124, and the fifth transistor T125 included in the twelfth pixel circuit PXC12 may be disposed on the eleventh well area W11 or the twelfth well area W12. For example, some of the second transistor T122, the third transistor T123, the fourth transistor T124, and the fifth transistor T125 may be disposed on the second portion W11B of the eleventh well area W11, and the others may be disposed on the twelfth well area W12. However, the present disclosure is not limited thereto, and in another embodiment, each of the second transistor T122, the third transistor T123, the fourth transistor T124, and the fifth transistor T125 included in the twelfth pixel circuit PXC12 may be disposed on the second portion W11B of the eleventh well area W11. In another embodiment, some of the second transistor T122, the third transistor T123, the fourth transistor T124, and the fifth transistor T125 may be disposed on the first portion W11A of the eleventh well area W11, and the others may be disposed on the twelfth well area W12.

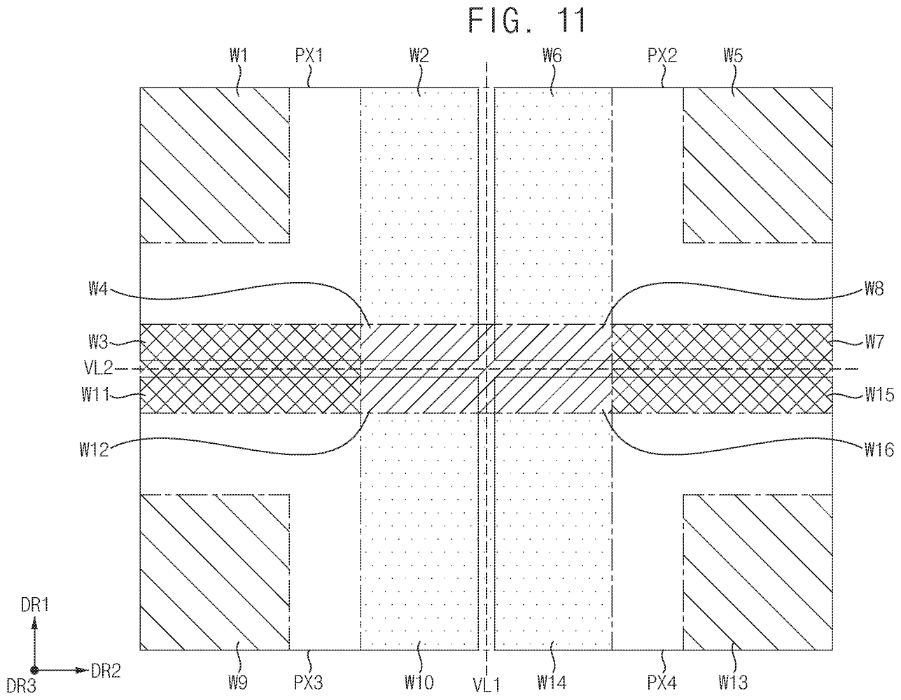

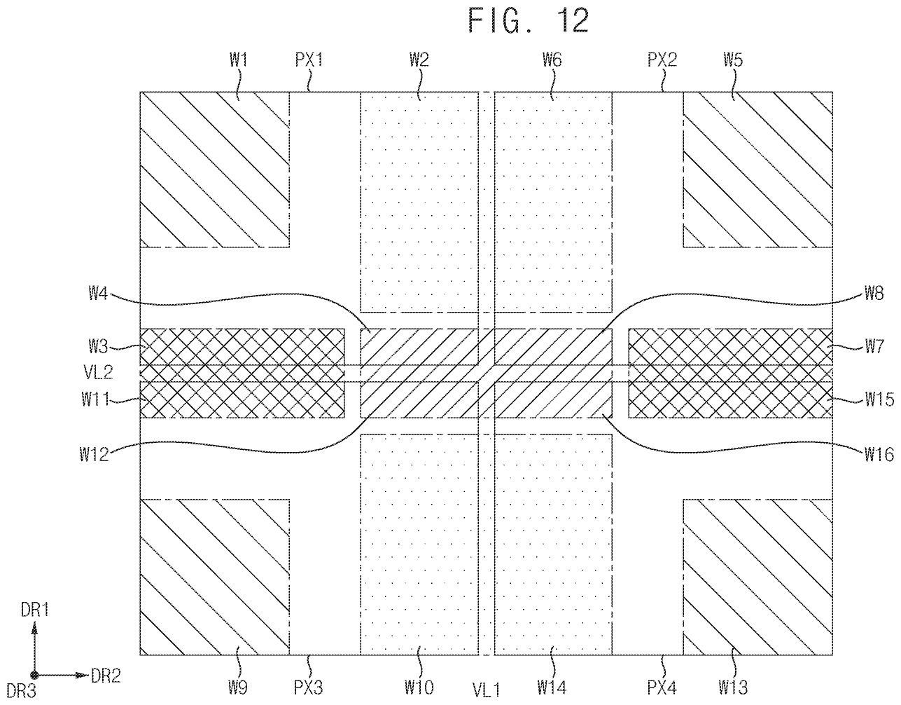

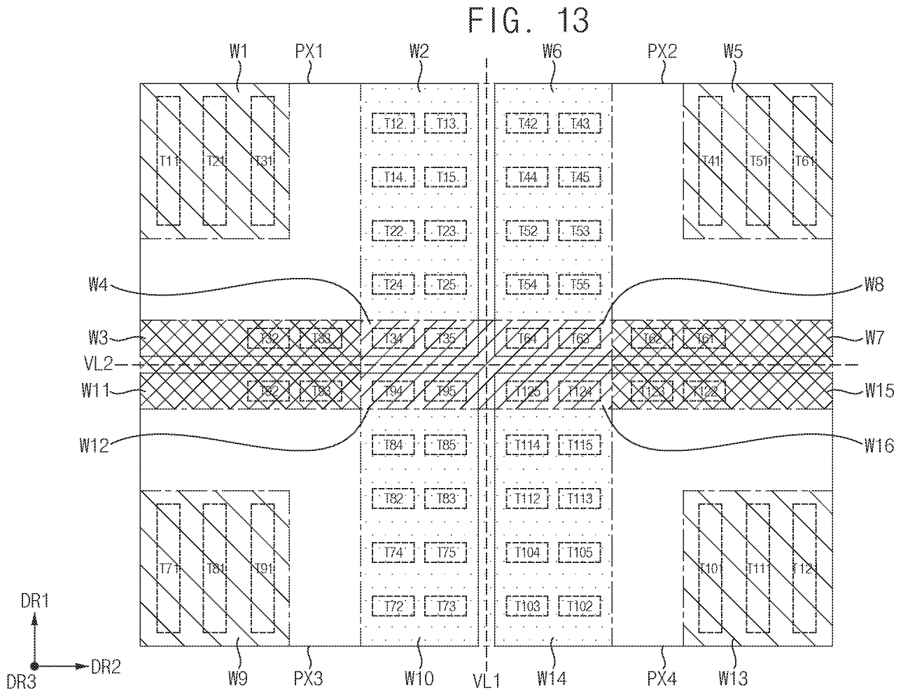

FIG. 11 is a schematic plan view illustrating a plurality of wells included in a display device according to an embodiment. FIG. 12 is a schematic plan view illustrating a plurality of wells included in a display device according to an embodiment. FIG. 13 is a schematic plan view illustrating a plurality of wells and transistors included in the display device of FIG. 12.

Redundant description of the components illustrated in FIGS. 11, 12, and 13 that are the same or substantially the same as those of the display device described above with reference to FIGS. 3, 4, and 5 may not be repeated.

Referring to FIG. 11, a first pixel PX1 may include a first well area W1, a second well area W2, a third well area W3, and a fourth well area W4. In an embodiment, the first well area W1 may have a rectangular shape in a plan view. However, the present disclosure is not limited thereto, and in another embodiment, the first well area W1 may have a shape different from the rectangular shape in a plan view.

The second well area W2 may be spaced apart from the first well area W1. The second well area W2 may extend in the first direction DR1. In other words, the second well area W2 may have a rectangular shape extending in the first direction DR1 in a plan view. In addition, the second well area W2 may be spaced apart from the first well area W1 in the second direction DR2.

The third well area W3 may extend in the second direction DR2. In other words, the third well area W3 may have a rectangular shape extending in the second direction DR2 in a plan view. In addition, the third well area W3 may be spaced apart from the first well area W1 in a direction opposite to the first direction DR1.

The fourth well area W4 may be in contact with the second well area W2 and the third well area W3. In an embodiment, the fourth well area W4 may have a rectangular shape in a plan view.

In an embodiment, the first well area W1 may have a voltage higher than a voltage of the second well area W2. In addition, the first well area W1 may have the voltage higher than a voltage of the third well area W3. In addition, the first well area W1 may have the voltage higher than a voltage of the fourth well area W4.

In addition, the second well area W2 may have the voltage different from the voltage of the third well area W3. In addition, the second well area W2 may have the voltage different from the voltage of the fourth well area W4. In addition, the third well area W3 may have the voltage different from the voltage of the fourth well area W4.

A second pixel PX2 may include a fifth well area W5, a sixth well area W6, a seventh well area W7, and an eighth well area W8. The fifth well area W5 may have a mirror image of the first well area W1 with respect to the first virtual line VL1.

The sixth well area W6 may have a mirror image of the second well area W2 with respect to the first virtual line VL1. In addition, the seventh well area W7 may have a mirror image of the third well area W3 with respect to the first virtual line VL1. In addition, the eighth well area W8 may have a mirror image of the fourth well area W4 with respect to the first virtual line VL1.

In an embodiment, the fifth well area W5 may have a voltage equal to or substantially equal to the voltage of the first well area W1. In addition, the sixth well area W6 may have a voltage equal to or substantially equal to the voltage of the second well area W2. In addition, the seventh well area W7 may have a voltage equal to or substantially equal to the voltage of the third well area W3. In addition, the eighth well area W8 may have a voltage equal to or substantially equal to the voltage of the fourth well area W4.

A third pixel PX3 may include a ninth well area W9, a tenth well area W10, an eleventh well area W11, and a twelfth well area W12. The ninth well area W9 may have a mirror image of the first well area W1 with respect to the second virtual line VL2.

The tenth well area W10 may have a mirror image of the second well area W2 with respect to the second virtual line VL2. In addition, the eleventh well area W11 may have a mirror image of the third well area W3 with respect to the second virtual line VL2. In addition, the twelfth well area W12 may have a mirror image of the fourth well area W4 with respect to the second virtual line VL2.

In an embodiment, the ninth well area W9 may have a voltage equal to or substantially equal to the voltage of the first well area W1. In addition, the tenth well area W10 may have a voltage equal to or substantially equal to the voltage of the second well area W2. In addition, the eleventh well area W11 may have a voltage equal to or substantially equal to the voltage of the third well area W3. In addition, the twelfth well area W12 may have a voltage equal to or substantially equal to the voltage of the fourth well area W4.

A fourth pixel PX4 may include a thirteenth well area W13, a fourteenth well area W14, a fifteenth well area W15, and a sixteenth well area W16. The thirteenth well area W13 may have a mirror image of the fourth well area W4 with respect to the first virtual line VL1.

The fourteenth well area W14 may have a mirror image of the tenth well area W10 with respect to the first virtual line VL1. In addition, the fifteenth well area W15 may have a mirror image of the eleventh well area W11 with respect to the first virtual line VL1. In addition, the sixteenth well area W16 may have a mirror image of the twelfth well area W12 with respect to the first virtual line VL1.

In an embodiment, the thirteenth well area W13 may have a voltage equal to or substantially equal to the voltage of the ninth well area W9. In addition, fourteenth well area W14 may have a voltage equal to or substantially equal to the voltage of the tenth well area W10. In addition, the fifteenth well area W15 may have a voltage equal to or substantially equal to the voltage of the eleventh well area W11. In addition, the sixteenth well area W16 may have a voltage equal to or substantially equal to the voltage of the twelfth well area W12.

Referring to FIG. 12, in another embodiment, the second well area W2 and the fourth well area W4 may be spaced apart (e.g., separated) from each other. In addition, the sixth well area W6 and the eighth well area W8 may be spaced apart (e.g., separated) from each other. In addition, the third well area W3 and the fourth well area W4 may be spaced apart (e.g., separated) from each other. In addition, the eleventh well area W11 and the twelfth well area W12 may be spaced apart (e.g., separated) from each other. In addition, the eighth well area W8 and the seventh well area W7 may be spaced apart (e.g., separated) from each other. In addition, the fifteenth well area W15 and the sixteenth well area W16 may be spaced apart (e.g., separated) from each other. In addition, the tenth well area W10 and the twelfth well area W12 may be spaced apart (e.g., separated) from each other. In addition, the fourteenth well area W14 and the sixteenth well area W16 may be spaced apart (e.g., separated) from each other.

Referring to FIG. 13, each of the first transistor T11 included in the first pixel circuit PXC1, the first transistor T21 included in the second pixel circuit PXC2, and the first transistor T31 included in the third pixel circuit PXC3 may be disposed in the first well area W1. In more detail, each of the first transistor T11 included in the first pixel circuit PXC1, the first transistor T21 included in the second pixel circuit PXC2, and the first transistor T31 included in the third pixel circuit PXC3 may be disposed on the first well area W1.

Each of the second transistor T12, the third transistor T13, the fourth transistor T14, and the fifth transistor T15 included in the first pixel circuit PXC1 may be disposed on the second well area W2, the third well area W3, or the fourth well area W4.

Each of the second transistor T22, the third transistor T23, the fourth transistor T24, and the fifth transistor T25 included in the second pixel circuit PXC2 may be disposed on the second well area W2, the third well area W3, or the fourth well area W4.

Each of the second transistor T32, the third transistor T33, the fourth transistor T34, and the fifth transistor T35 included in the third pixel circuit PXC3 may be disposed on the second well area W2, the third well area W3, or the fourth well area W4.

Each of the first transistor T41 included in the fourth pixel circuit PX4, the first transistor T51 included in the fifth pixel circuit PXC5, and the first transistor T61 included in the sixth pixel circuit PXC6 may be disposed in the fifth well area W5. In more detail, each of the first transistor T41 included in the fourth pixel circuit PX4, the first transistor T51 included in the fifth pixel circuit PXC5, and the first transistor T61 included in the sixth pixel circuit PXC6 may be disposed on the fifth well area W5.

Each of the second transistor T42, the third transistor T43, the fourth transistor T44, and the fifth transistor T45 included in the fourth pixel circuit PXC4 may be disposed on the sixth well area W6, the seventh well area W7, or the eighth well area W8.

Each of the second transistor T52, the third transistor T53, the fourth transistor T54, and the fifth transistor T55 included in the fifth pixel circuit PXC5 may be disposed on the sixth well area W6, the seventh well area W7, or the eighth well area W8.

Each of the second transistor T62, the third transistor T63, the fourth transistor T64, and the fifth transistor T65 included in the sixth pixel circuit PXC6 may be disposed on the sixth well area W6, the seventh well area W7, or the eighth well area W8.

Each of the first transistor T71 included in the seventh pixel circuit PX7, the first transistor T81 included in the eighth pixel circuit PXC8, and the first transistor T91 included in the ninth pixel circuit PXC9 may be disposed in the ninth well area W9. In more detail, each of the first transistor T71 included in the seventh pixel circuit PX7, the first transistor T81 included in the eighth pixel circuit PXC8, and the first transistor T91 included in the ninth pixel circuit PXC9 may be disposed on the ninth well area W9.

Each of the second transistor T72, the third transistor T73, the fourth transistor T74, and the fifth transistor T75 included in the seventh pixel circuit PXC7 may be disposed on the tenth well area W10, the eleventh well area W11, or the twelfth well area W12.

Each of the second transistor T82, the third transistor T83, the fourth transistor T84, and the fifth transistor T85 included in the eighth pixel circuit PXC8 may be disposed on the tenth well area W10, the eleventh well area W11, or the twelfth well area W12.

Each of the second transistor T92, the third transistor T93, the fourth transistor T94, and the fifth transistor T95 included in the ninth pixel circuit PXC9 may be disposed on the tenth well area W10, the eleventh well area W11, or the twelfth well area W12.

Each of the first transistor T101 included in the tenth pixel circuit PX10, the first transistor T111 included in the eleventh pixel circuit PXC11, and the first transistor T121 included in the twelfth pixel circuit PXC12 may be disposed in the thirteenth well area W13. In more detail, each of the first transistor T101 included in the tenth pixel circuit PX10, the first transistor T111 included in the eleventh pixel circuit PXC11, and the first transistor T121 included in the twelfth pixel circuit PXC12 may be disposed on the thirteenth well area W13.

Each of the second transistor T102, the third transistor T103, the fourth transistor T104, and the fifth transistor T105 included in the tenth pixel circuit PXC10 may be disposed on the fourteenth well area W14, the fifteenth well area W15, or the sixteenth well area W16.

Each of the second transistor T112, the third transistor T113, the fourth transistor T114, and the fifth transistor T115 included in the eleventh pixel circuit PXC11 may be disposed on the fourteenth well area W14, the fifteenth well area W15, or the sixteenth well area W16.

Each of the second transistor T122, the third transistor T123, the fourth transistor T124, and the fifth transistor T125 included in the twelfth pixel circuit PXC12 may be disposed on the fourteenth well area W14, the fifteenth well area W15, or the sixteenth well area W16.

Embodiments of the present disclosure described above may be applied to various suitable display devices. For example, embodiments of the present disclosure may be applicable to various suitable display devices, such as display devices for vehicles, ships, aircrafts, and the like, portable communication devices, display devices for exhibition or information transmission, medical display devices, and the like.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in a suitable combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a substrate comprising:
a first well area; and
a second well area spaced from the first well area, the second well area having a voltage different from a voltage of the first well area;
a first pixel circuit comprising:
a first transistor located on the first well area; and
a second transistor located on the second well area; and
a second pixel circuit comprising:
a third transistor located on the first well area; and
a fourth transistor located on the second well area.

2. The display device of claim 1, wherein the voltage of the first well area is higher than the voltage of the second well area.

3. The display device of claim 2, wherein the first well area has a rectangular shape, and the second well area comprises:
a first portion extending in a first direction, and spaced from the first well area in a second direction crossing the first direction;
a second portion extending in the second direction, and spaced from the first well area in the first direction; and
a third portion in contact with the first portion and the second portion.

4. The display device of claim 2, wherein each of the first transistor and the third transistor is a driving transistor of a corresponding pixel circuit.

5. The display device of claim 2, further comprising a third pixel circuit comprising:
a fifth transistor located on the first well area; and
a sixth transistor located on the second well area.

6. The display device of claim 5, wherein the fifth transistor is a driving transistor.

7. The display device of claim 2, wherein the substrate further comprises:
a third well area having a structure corresponding to a mirror image of that of the first well area with respect to a first direction, the third well area having a voltage equal to the voltage of the first well area; and
a fourth well area having a structure corresponding to a mirror image of that of the second well area with respect to the first direction, the fourth well area having a voltage equal to the voltage of the second well area, and
wherein the display device further comprises:
a fourth pixel circuit comprising a seventh transistor located on the third well area, and an eighth transistor located on the fourth well area;
a fifth pixel circuit comprising a ninth transistor located on the third well area, and a tenth transistor located on the fourth well area; and
a sixth pixel circuit comprising an eleventh transistor located on the third well area, and a twelfth transistor located on the fourth well area.

8. The display device of claim 7, wherein each of the seventh transistor, the ninth transistor, and the eleventh transistor is a driving transistor of a corresponding pixel circuit.

9. The display device of claim 8, wherein the substrate further comprises:
a fifth well area having a structure corresponding to a mirror image of that of the first well area with respect to a second direction crossing the first direction, the fifth well area having a voltage equal to the voltage of the first well area; and
a sixth well area having a structure corresponding to a mirror image of that of the second well area with respect to the second direction, the sixth well area having a voltage equal to the voltage of the second well area, and
wherein the display device further comprises:
a seventh pixel circuit comprising a thirteenth transistor located on the fifth well area, and a fourteenth transistor located on the sixth well area;
an eighth pixel circuit comprising a fifteenth transistor located on the fifth well area, and a sixteenth transistor located on the sixth well area; and
a ninth pixel circuit comprising a seventeenth transistor located on the fifth well area, and an eighteenth transistor located on the sixth well area.

10. The display device of claim 9, wherein each of the thirteenth transistor, the fifteenth transistor, and the seventeenth transistor is a driving transistor of a corresponding pixel circuit.

11. The display device of claim 10, wherein the substrate further comprises:
a seventh well area having a structure corresponding to a mirror image of that of the fifth well area with respect to the first direction, the seventh well area having a voltage equal to the voltage of the fifth well area; and
an eighth well area having a structure corresponding to a mirror image of that of the sixth well area with respect to the first direction, the eighth well area having a voltage equal to the voltage of the sixth well area, and
wherein the display device further comprises:
a tenth pixel circuit comprising a nineteenth transistor located on the seventh well area, and a twentieth transistor located on the eighth well area;
an eleventh pixel circuit comprising a twenty-first transistor located on the seventh well area, and a twenty-second transistor located on the eighth well area; and
a twelfth pixel circuit comprising a twenty-third transistor located on the seventh well area, and a twenty-fourth transistor located on the eighth well area.

12. The display device of claim 11, wherein each of the nineteenth transistor, the twenty-first transistor, and the twenty-third transistor is a driving transistor of a corresponding pixel circuit.

13. A display device comprising:
a substrate comprising:
a first well area having a rectangular shape;
a second well area having a voltage lower than a voltage of the first well area, and comprising:
a first portion extending in a first direction, and spaced from the first well area in a second direction crossing the first direction; and
a second portion extending in the second direction, and spaced from the first well area in the first direction; and
a third well area having a voltage lower than the voltage of the first well area and different from the voltage of the second well area, and in contact with the first portion and the second portion;
a first pixel circuit comprising:
a first transistor located on the first well area; and
a second transistor located on the second well area or the third well area;
a second pixel circuit comprising:
a third transistor located on the first well area; and
a fourth transistor located on the second well area or the third well area; and
a third pixel circuit comprising:
a fifth transistor located on the first well area; and
a sixth transistor located on the second well area or the third well area.

14. The display device of claim 13, wherein the substrate further comprises:
a fourth well area having a structure corresponding to a mirror image of that of the first well area with respect to the first direction, the fourth well area having a voltage equal to the voltage of the first well area;
a fifth well area having a structure corresponding to a mirror image of that of the second well area with respect to the first direction, the fifth well area having a voltage equal to the voltage of the second well area; and
a sixth well area having a structure corresponding to a mirror image of that of the third well area with respect to the first direction, the sixth well area having a voltage equal to the voltage of the third well area,
wherein the display device further comprises:
a fourth pixel circuit comprising:
a seventh transistor located on the fourth well area; and
an eighth transistor located on the fifth well area or the sixth well area;
a fifth pixel circuit comprising:
a ninth transistor located on the fourth well area; and
a tenth transistor located on the fifth well area or the sixth well area; and
a sixth pixel circuit comprising:
an eleventh transistor located on the fourth well area; and
a twelfth transistor located on the fifth well area or the sixth well area, and
wherein each of the seventh transistor, the ninth transistor, and the eleventh transistor is a driving transistor of a corresponding pixel circuit.

15. The display device of claim 14, wherein the substrate further comprises:
a seventh well area having a structure corresponding to a mirror image of that of the first well area with respect to the second direction, the seventh well area having a voltage equal to the voltage of the first well area;
an eighth well area having a structure corresponding to a mirror image of that of the second well area with respect to the second direction, the eighth well area having a voltage equal to the voltage of the second well area; and
a ninth well area having a structure corresponding to a mirror image of that of the third well area with respect to the second direction, the ninth well area having a voltage equal to the voltage of the third well area,
wherein the display device further comprises:
a seventh pixel circuit comprising:
a thirteenth transistor located on the seventh well area; and
a fourteenth transistor located on the eighth well area or the ninth well area;
an eighth pixel circuit comprising:
a fifteenth transistor located on the seventh well area; and
a sixteenth transistor located on the eighth well area or the ninth well area; and
a ninth pixel circuit comprising:
a seventeenth transistor located on the seventh well area; and
an eighteenth transistor located on the eighth well area or the ninth well area, and
wherein each of the thirteenth transistor, the fifteenth transistor, and the seventeenth transistor is a driving transistor of a corresponding pixel circuit.

16. The display device of claim 15, wherein the substrate further comprises:
a tenth well area having a structure corresponding to a mirror image of that of the seventh well area with respect to the first direction, the tenth well area having a voltage equal to the voltage of the seventh well area;
an eleventh well area having a structure corresponding to a mirror image of that of the eighth well area with respect to the first direction, the eleventh well area having a voltage equal to the voltage of the eighth well area; and
a twelfth well area having a structure corresponding to a mirror image of that of the ninth well area with respect to the first direction, the twelfth well area having a voltage equal to the voltage of the ninth well area,
wherein the display device further comprises:
a tenth pixel circuit comprising:
a nineteenth transistor located on the tenth well area; and
a twentieth transistor located on the eleventh well area or the twelfth well area;
an eleventh pixel circuit comprising:
a twenty-first transistor located on the tenth well area; and
a twenty-second transistor located on the eleventh well area or the twelfth well area; and
a twelfth pixel circuit comprising:
a twenty-third transistor located on the tenth well area; and
a twenty-fourth transistor located on the eleventh well area or the twelfth well area, and
wherein each of the nineteenth transistor, the twenty-first transistor, and the twenty-third transistor is a driving transistor of a corresponding pixel circuit.

17. A display device comprising:
a substrate comprising:
a first well area having a rectangular shape;
a second well area having a voltage lower than a voltage of the first well area, extending in a first direction, and spaced from the first well area in a second direction crossing the first direction;
a third well area having a voltage lower than the voltage of the first well area and different from the voltage of the second well area, extending in the second direction, and spaced from the first well area in the first direction; and
a fourth well area having a voltage lower than the voltage of the first well area and different from each of the voltage of the second well area and the voltage of the third well area, and in contact with the second well area and the third well area;
a first pixel circuit comprising:
a first transistor located on the first well area; and
a second transistor located on the second well area, the third well area, or the fourth well area;
a second pixel circuit comprising:
a third transistor located on the first well area; and
a fourth transistor located on the second well area, the third well area, or the fourth well area; and
a third pixel circuit comprising:
a fifth transistor located on the first well area; and
a sixth transistor located on the second well area, the third well area, or the fourth well area.

18. The display device of claim 17, wherein the substrate further comprises:
a fifth well area having a structure corresponding to a mirror image of that of the first well area with respect to the first direction, the fifth well area having a voltage equal to the voltage of the first well area;
a sixth well area having a structure corresponding to a mirror image of that of the second well area with respect to the first direction, the sixth well area having a voltage equal to the voltage of the second well area;
a seventh well area having a structure corresponding to a mirror image of that of the third well area with respect to the first direction, the seventh well area having a voltage equal to the voltage of the third well area; and
an eighth well area having a structure corresponding to a mirror image of that of the fourth well area with respect to the first direction, the eighth well area having a voltage equal to the voltage of the fourth well area,
wherein the display device further comprises:
a fourth pixel circuit comprising:
a seventh transistor located on the fifth well area; and
an eighth transistor located on the sixth well area, the seventh well area, or the eighth well area;
a fifth pixel circuit comprising:
a ninth transistor located on the fifth well area; and
a tenth transistor located on the sixth well area, the seventh well area, or the eighth well area; and
a sixth pixel circuit comprising:
a eleventh transistor located on the fifth well area; and
a twelfth transistor located on the sixth well area, the seventh well area, or the eighth well area, and
wherein each of the seventh transistor, the ninth transistor, and the eleventh transistor is a driving transistor of a corresponding pixel circuit.

19. The display device of claim 18, wherein the substrate further comprises:
a ninth well area having a structure corresponding to a mirror image of that of the first well area with respect to the second direction, the ninth well area having a voltage equal to the voltage of the first well area;
a tenth well area having a structure corresponding to a mirror image of that of the second well area with respect to the second direction, the tenth well area having a voltage equal to the voltage of the second well area;
an eleventh well area having a structure corresponding to a mirror image of that of the third well area with respect to the second direction, the eleventh well area having a voltage equal to the voltage of the third well area; and
a twelfth well area having a structure corresponding to a mirror image of the fourth well area with respect to the second direction, the twelfth well area having a voltage equal to the voltage of the fourth well area,
wherein the display device further comprises:
a seventh pixel circuit comprising:
a thirteenth transistor located on the ninth well area; and
a fourteenth transistor located on the tenth well area, the eleventh well area, or the twelfth well area;
an eighth pixel circuit comprising:
a fifteenth transistor located on the ninth well area; and
a sixteenth transistor located on the tenth well area, the eleventh well area, or the twelfth well area; and
a ninth pixel circuit comprising:
a seventeenth transistor located on the ninth well area; and
an eighteenth transistor located on the tenth well area, the eleventh well area, or the twelfth well area, and
wherein each of the thirteenth transistor, the fifteenth transistor, and the seventeenth transistor is a driving transistor of a corresponding pixel circuit.

20. The display device of claim 19, wherein the substrate further comprises:
a thirteenth well area having a structure corresponding to a mirror image of that of the ninth well area with respect to the first direction, the thirteenth well area having a voltage equal to the voltage of the ninth well area;
a fourteenth well area having a structure corresponding to a mirror image of that of the tenth well area with respect to the first direction, the fourteenth well area having a voltage equal to the voltage of the tenth well area;
a fifteenth well area having a structure corresponding to a mirror image of the eleventh well area with respect to the first direction, the fifteenth well area having a voltage equal to the voltage of the eleventh well area; and
a sixteenth well area having a structure corresponding to a mirror image of that of the twelfth well area with respect to the first direction, the sixteenth well area having a voltage equal to the voltage of the twelfth well area,
wherein the display device further comprises:
a tenth pixel circuit comprising:
a nineteenth transistor located on the thirteenth well area; and
a twentieth transistor located on the fourteenth well area, the fifteenth well area, or the sixteenth well area;
an eleventh pixel circuit comprising:
a twenty-first transistor located on the thirteenth well area; and
a twenty-second transistor located on the fourteenth well area, the fifteenth well area, or the sixteenth well area; and
a twelfth pixel circuit comprising:
a twenty-third transistor located on the thirteenth well area; and
a twenty-fourth transistor located on the fourteenth well area, the fifteenth well area, or the sixteenth well area, and
wherein each of the nineteenth transistor, the twenty-first transistor, and the twenty-third transistor is a driving transistor of a corresponding pixel circuit.
